(19) United States
(12) Patent Application Publication
(10) Pub. No.: US 2025/0163081 A1
(43) Pub. Date: May 22, 2025

(54) SILICON COMPOUNDS AND METHODS OF MANUFACTURING INTEGRATED CIRCUIT DEVICE USING THE SAME

(71) Applicant: Samsung Electronics Co., Ltd., Suwon-si (KR)

(72) Inventors: Hyunwoo Kim, Seoul (KR); Sunggi Kim, Daejeon (KR); Yeonghun Kim, Daejeon (KR); Samdong Lee, Daejeon (KR); Sejin Jang, Jeju-si (KR); Gyuhee Park, Hwaseong-si (KR); Younjoung Cho, Hwaseong-si (KR); Byungkeun Hwang, Seongnam-si (KR)

(73) Assignees: DNF Co., Ltd., Daejeon (KR); Samsung Electronics Co., Ltd., Suwon-si (KR)

(21) Appl. No.: 19/029,416

(22) Filed: Jan. 17, 2025

Related U.S. Application Data
(63) Continuation of application No. 17/573,691, filed on Jan. 12, 2022.

(30) Foreign Application Priority Data
May 14, 2021 (KR) 10-2021-0062947

(51) Int. Cl. C07F 7/08; H01L 21/768

(52) U.S. Cl. CPC C07F 7/0816; H01L 21/76831

(57) ABSTRACT

Silicon compounds may be represented by the following formula:

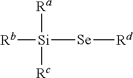

Each of R^{a}, R^{b}, and R^{c} may be a hydrogen atom, a halogen atom, a C1-C7 alkyl group, an amino group, a C1-C7 alkyl amino group, or a C1-C7 alkoxy group, R^{d} may be a C1-C7 alkyl group, a C1-C7 alkyl amino group, or a silyl group represented by a formula of *—Si(X¹)(X²)(X³). Each of X¹, X², and X³ may be a hydrogen atom, a halogen atom, a C1-C7 alkyl group, an amino group, a C1-C7 alkyl amino group, or a C1-C7 alkoxy group, and * is a bonding site. In some embodiments, when R^{b} is the C1-C7 alkyl amino group and R^{d} is the C1-C7 alkyl group, R^{b} may be connected to R^{d} to form a ring. To manufacture an integrated circuit (IC) device, a silicon-containing film may be formed on a substrate using the silicon compound of the formula provided above.

### CROSS-REFERENCE TO RELATED APPLICATION

This application claims priority under 35 U.S.C. § 119 to Korean Patent Application No. 10-2021-0062947, filed on May 14, 2021, in the Korean Intellectual Property Office, the disclosure of which is incorporated by reference herein in its entirety.

### BACKGROUND

The inventive concept relates to a silicon compound and a method of manufacturing an integrated circuit (IC) device using the silicon compound, and more particularly, a silicon compound used to form a silicon-containing film, and a method of manufacturing an IC device including the silicon compound.

Due to the development of electronics technology, the downscaling of semiconductor devices has rapidly progressed. Accordingly, the area of device regions has been reduced, and an aspect ratio of unit elements has increased. Also, there is a need for a technique of forming a silicon-containing film having a uniform thickness and excellent electrical properties at a relatively low temperature. In addition, it is necessary to develop silicon compounds for forming silicon-containing films, which may provide a stable deposition process at a low temperature, provide excellent gap-fill characteristics, step coverage characteristics, and etching characteristics during the formation of a silicon-containing film due to the ease of handling, and thus are advantageous in terms of process stability and mass productivity.

### SUMMARY

The inventive concept provides silicon compounds, which enables formation of a thin film at a uniform thickness under conditions of relatively low process temperatures and is easy to handle, and thus, the silicon compounds may provide excellent gap-fill characteristics, step coverage characteristics, and etching characteristics when used as a source compound for forming a silicon-containing film and improve process stability and mass productivity.

The inventive concept also provides methods of manufacturing an integrated circuit (IC) device, by which a silicon-containing film of good quality may be formed using a silicon compound capable of providing excellent process stability and mass productivity to improve electrical properties and productivity

According to an aspect of the inventive concept, there are provided silicon compounds represented by the following General formula (1),

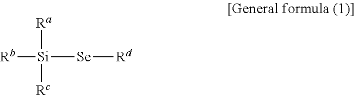

wherein each of R^{a}, R^{b}, and R^{c} may be independently a hydrogen atom, a halogen atom, a C1-C7 straight-chain alkyl group, a C3-C7 branched alkyl group, an amino group, a C1-C7 alkyl amino group, or a C1-C7 alkoxy group,

R^{d} may be a C1-C7 straight-chain alkyl group, a C3-C7 branched alkyl group, a C1-C7 alkyl amino group, or a substituted or unsubstituted silyl group represented by a formula of *—Si(X¹)(X²)(X³), wherein each of X¹, X², and X³ may be independently a hydrogen atom, a halogen atom, a C1-C7 straight-chain alkyl group, a C3-C7 branched alkyl group, an amino group, a C1-C7 alkyl amino group, or a C1-C7 alkoxy group, and * is a bonding site.

When R^{b}is the C1-C7 alkyl amino group and R^{d} is the C1-C7 straight-chain alkyl group or the C3-C7 branched alkyl group, R^{b} may be connected (e.g., bonded) to R^{d} to form a ring.

According to another aspect of the inventive concept, there are provided methods of manufacturing an IC device. The methods may include forming a silicon-containing film on a substrate using a silicon compound of General formula (1).

According to another aspect of the inventive concept, there are provided methods of manufacturing an IC device. The methods may include forming a first conductive line on a substrate. The first conductive line may extend in a first lateral direction. A plurality of memory cells may be formed on the first conductive line. A silicon-containing insulating liner may be formed on (e.g., formed to cover) an exposed surface of each of the plurality of memory cells. A gap-fill insulating film may be formed on the silicon-containing insulating liner, in some embodiments, to fill spaces between the plurality of memory cells. A plurality of second conductive lines may be formed on the plurality of memory cells. The plurality of second conductive lines may extend longitudinally in a second lateral direction and may be each connected to one of the plurality of memory cells. The second lateral direction may be different from the first lateral direction. In some embodiments, the second lateral direction may intersect with the first lateral direction. To form the silicon-containing insulating liner, a silicon compound of General formula (1) may be supplied onto the substrate, and thus, a chemisorbed layer of the silicon compound may be formed on a surface of each of the plurality of memory cells. A reactive gas including a nitrogen atom may be supplied onto the resultant structure including the chemisorbed layer of the silicon compound to form a silicon nitride film.

### BRIEF DESCRIPTION OF THE DRAWINGS

Example embodiments of the inventive concept will be more clearly understood from the following detailed description taken in conjunction with the accompanying drawings in which:

FIG. 1 is a flowchart of a method of manufacturing an integrated circuit (IC) device, according to some embodiments of the inventive concept;

FIG. 2 is a flowchart of a method of forming a silicon-containing film of an IC device, according to some embodiments of the inventive concept;

FIGS. 3A, 3B, 3C, 3D, 3E, 3F, 3G, 3H, 3I and 3J are cross-sectional views illustrating a method of manufacturing an IC device, according to some embodiments of the inventive concept;

FIG. 4 is a graph showing nuclear magnetic resonance (NMR) spectrum of a silicon compound according to some embodiments of the inventive concept;

FIG. 5 is a graph showing thermogravimetric analysis (TGA) results of a silicon compound according to embodiments;

FIG. 6 is a graph showing TGA results of a silicon compound according to some embodiments of the inventive concept;

FIG. 7 is a graph showing vapor pressure of a silicon compound according to some embodiments of the inventive concept;

FIG. 8 is a graph showing vapor pressure of a silicon compound according to some embodiments of the inventive concept;

FIGS. 9, 10 and 11 are each graphs showing components of silicon-containing films formed using a silicon compound according to some embodiments of the inventive concept;

FIG. 12 is a graph showing components of a silicon-containing film formed using a silicon compound according to embodiments of the inventive concept; and

FIG. 13 is a graph showing estimated results of a wet etching process on a silicon-containing film formed using a silicon compound according to some embodiments of the inventive concept.

### DETAILED DESCRIPTION

Hereinafter, example embodiments of the inventive concept will be described in detail with reference to the accompanying drawings. The same reference numerals refer to the same elements, and repeated descriptions thereof may be omitted.

When the term “substrate” is used herein, it should be understood as either the substrate itself or a structure including the substrate and a layer or film formed on a surface of the substrate. When the expression “a surface of a substrate” is used herein, it should be understood as either as an exposed surface of the substrate itself or an outer surface of a layer or film formed on the substrate. As used herein, the term “room temperature” refers to a temperature ranging from about 20° C. to about 28° C. and may vary depending on the season.

The silicon compound according to embodiments of the inventive concept may be represented by the following General formula (1):

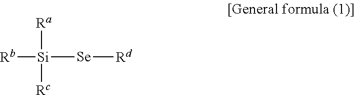

wherein each of R^{a}, R^{b}, and R^{c} may be independently a hydrogen atom, a halogen atom, a C1-C7 straight-chain alkyl group, a C3-C7 branched alkyl group, an amino group, a C1-C7 alkyl amino group, or a C1-C7 alkoxy group,

R^{d} may be a C1-C7 straight-chain alkyl group, a C3-C7 branched alkyl group, a C1-C7 alkyl amino group, or a substituted or unsubstituted silyl group represented by a formula of *—Si(X¹)(X²)(X³), wherein each of X¹, X², and X³ may be independently a hydrogen atom, a halogen atom, a C1-C7 straight-chain alkyl group, a C3-C7 branched alkyl group, an amino group, a C1-C7 alkyl amino group, or a C1-C7 alkoxy group, and * may be a bonding site.

When R^{b} is a C1-C7 alkyl amino group, and R^{d} is a C1-C7 straight-chain alkyl group or a C3-C7 branched alkyl group, R^{b} may be connected to R^{d} to form a ring. In some embodiments, R^{d}, together with R^{a}, R^{b}, or R^{c}, forms a C2-C14 cyclic aminoalkyl group.

In example embodiments, at least one of R^{a}, R^{b}, R^{c}, X¹, X², and X³ may be an alkyl group, and the alkyl group may be a methyl group, an ethyl group, an n-propyl group, an isopropyl group, an n-butyl group, an isobutyl group, a sec-butyl group, a tert-butyl group, an n-pentyl group, an isopentyl group, a sec-pentyl group, a tert-pentyl group, a neopentyl group, a 3-pentyl group, an n-hexyl group, or an n-heptyl group. For example, at least one of R^{a}, R^{b}, and R^{c} may be a methyl group or an isopropyl group.

In example embodiments, when at least one of R^{a}, R^{b}, R^{c}, X¹, X², and X³ is an alkyl group, the at least one of R^{a}, R^{b}, R^{c}, X¹, X², and X³ may be a fluoroalkyl group in which some or all of hydrogen atoms included in the alkyl group are substituted with fluorine atoms. For example, at least one of R^{a}, R^{b}, R^{c}, X¹, X², and X³ may be a C1-C7 straight-chain perfluoroalkyl group or a C3-C5 branched perfluoroalkyl group in which all of the hydrogen atoms included in the alkyl group are substituted with fluorine atoms.

In example embodiments, when at least one of R^{a}, R^{b}, R^{c}, X¹, X², and X³ is a branched alkyl group, the silicon compound of General formula (1) may be a liquid phase at room temperature.

As used herein, the term “alkyl amino group” refers to an amino group substituted with one or two C1-C7 alkyl groups. The alkyl amino group may be a monoalkyl amino group or a dialkyl amino group. In example embodiments, the alkyl amino group may include a methylamino group, a dimethylamino group, an ethylamino group, a diethylamino group, a propylamino group, a dipropylamino group, an isopropylamino group, a diisopropylamino group, a butylamino group, an isobutylamino group, an s-butylamino group, a t-butylamino group, a pentylamino group, a hexylamino group, a cyclohexylamino group, and/or a heptylamino group, without being limited thereto.

The halogen atom may be a fluorine atom, a chlorine atom, a bromine atom, or an iodine atom.

The alkoxy group may include, for example, a methoxy group, an ethoxy group, a propyloxy group, an isopropyloxy group, a butoxy group, an isobutoxy group, an s-butoxy group, a t-butoxy group, a pentyloxy group, a hexyloxy group, or a heptyloxy group.

The substituted or unsubstituted silyl group may include, for example, a silyl group (—SiH₃), a C1-C7 monoalkylsilyl group, a C1-C7 dialkylsilyl group, or a C1-C7 trialkylsilyl group. The alkyl group included in the monoalkylsilyl group, the dialkylsilyl group, and the trialkylsilyl group may include a straight-chain alkyl group or a branched alkyl group.

In example embodiments, in General formula (1), at least one of R^{a}, R^{b}, R^{c}, and R^{d} may include a halogen atom, a nitrogen atom, or an oxygen atom.

In example embodiments, in General formula (1), at least one of R^{a}, R^{b}, R^{c}, and R^{d} may include a halogen atom, and the halogen atom may be an iodine atom.

In example embodiments, in General formula (1), R^{d} may be a substituted or unsubstituted silyl group represented by a formula of *—Si(X¹)(X²)(X³). In this case, the silicon compound of General formula (1) may have a linear structure represented by the following General formula (2):

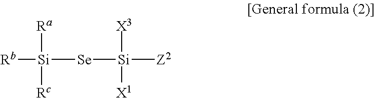

wherein each of R^{a}, R^{b}, R^{c}, X¹, X², and X³ is the same as defined above. In some embodiments, at least one of X¹, X², and X³ may be a halogen atom, an amino group, a C1-C7 alkyl amino group, or a C1-C7 alkoxy group.

In example embodiments, in General formula (2), a case in which all substituents of R^{a}, R^{b}, R^{c}, X¹, X², and X³ are hydrogen atoms or alkyl groups may be excluded. In this case, a silicon compound of General formula (2) may provide relatively good physical properties in a process of forming a silicon-containing film.

In example embodiments, the silicon compound according to some embodiments may have a linear structure represented by one selected from General formula (3), General formula (4), General formula (5), and General formula (6):

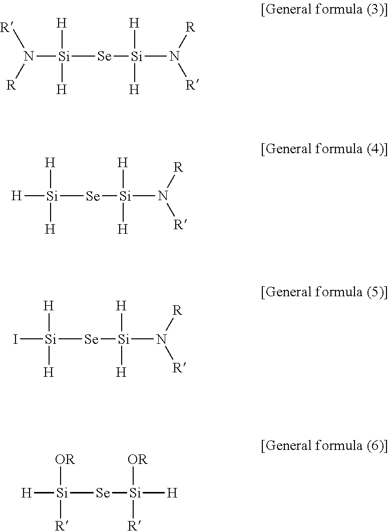

In General formula (3), General formula (4), General formula (5), and General formula (6), each of R and R′ may be independently a hydrogen atom, a C1-C4 straight-chain alkyl group, or a C3-C4 branched alkyl group. For example, each of R and R′ may be independently a hydrogen atom, a methyl group, or a t-butyl group, without being limited thereto.

In example embodiments, the silicon compound according to some embodiments may have a linear structure selected from the following Formulae 1 to 12, but the inventive concept is not limited thereto.

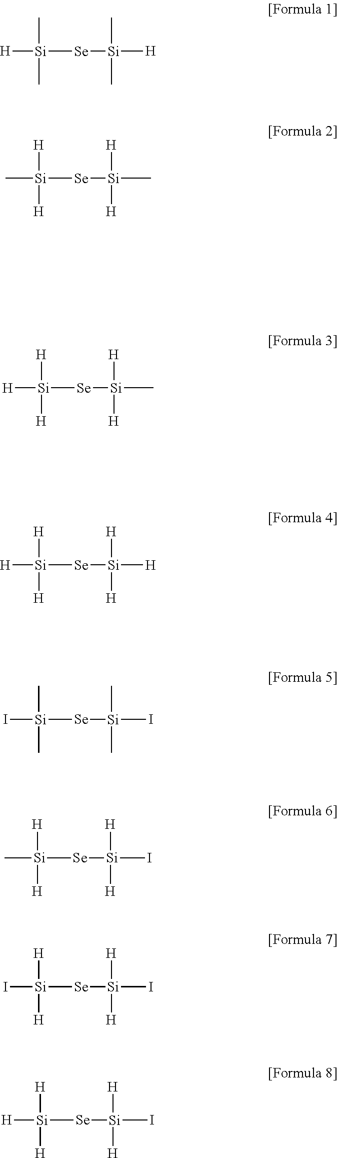

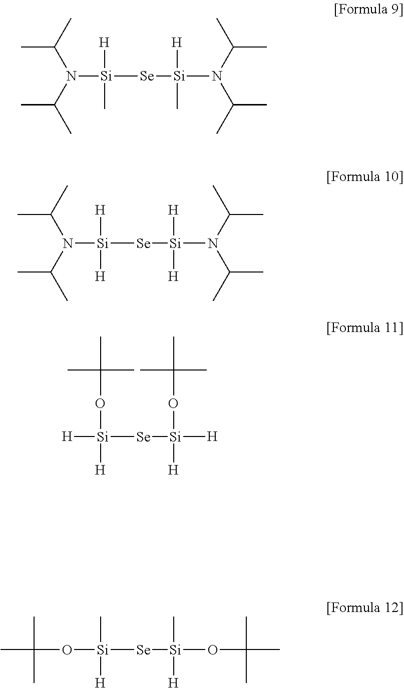

In other example embodiments, the silicon compound of General formula (1) may have a cyclic structure including a bonding unit of *—Se—Si(R¹)(R²)—N(R³)—*. Here, each of R¹ and R² may be independently a hydrogen atom, a halogen atom, a C1-C7 straight-chain alkyl group, a C3-C7 branched alkyl group, an amino group, a C1-C7 alkyl amino group, or a C1-C7 alkoxy group, R³ may be a hydrogen atom, a C1-C7 straight-chain alkyl group, or a C3-C7 branched alkyl group, and * denotes a bonding site.

For example, the silicon compound according to some embodiments may have a cyclic structure represented by the following General formula (8):

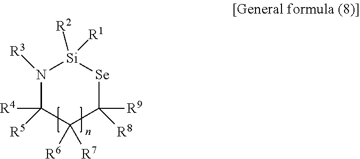

wherein each of R¹ and R² may be independently a hydrogen atom, a halogen atom, a C1-C7 straight-chain alkyl group, a C3-C7 branched alkyl group, an amino group, a C1-C7 alkyl amino group, or a C1-C7 alkoxy group, each of R³, R⁴, R⁵, R⁶, R⁷, R⁸ and R⁹ may be independently a hydrogen atom, a C1-C7 straight-chain alkyl group, or a C3-C7 branched alkyl group, and n may be 0 or 1.

In example embodiments, each of R¹ and R² may be independently a hydrogen atom, a halogen atom, a C1-C4 straight-chain alkyl group, a C3-C4 branched alkyl group, an amino group, a C1-C4 alkyl amino group, or a C1-C4 alkoxy group, each of R³, R⁴, R⁵, R⁶, R⁷, R⁸ and R⁹ may be independently a hydrogen atom, a C1-C4 straight-chain alkyl group, or a C3-C4 branched alkyl group, and n may be 0.

In example embodiments, the silicon compound according to some embodiments may have a cyclic structure represented by General formula (9) or General formula (10):

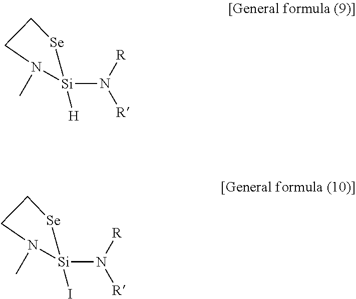

In General formulae (9) and (10), each of R and R′ may be independently a hydrogen atom, a C1-C4 straight-chain alkyl group, or a C3-C4 branched alkyl group. For example, each of R and R′ may be independently a hydrogen atom, a methyl group, or a t-butyl group, without being limited thereto.

In example embodiments, the silicon compound according to some embodiments may have a cyclic structure selected from the following Formulae 13 to 20, but the inventive concept is not limited thereto.

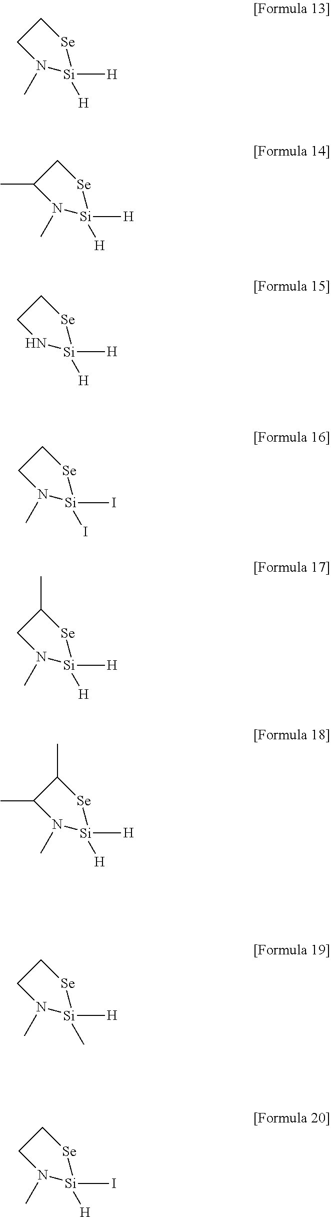

The silicon compound according to some embodiments may be liquid at room temperature. For example, the silicon compound according to some embodiments may be liquid at a temperature of about 25° C.

A silicon compound according to some embodiments may have relatively low activation energy and relatively high thermal stability and may provide excellent reactivity as a silicon precursor for forming a silicon-containing film. In addition, when a silicon-containing film is formed using the silicon compound according to some embodiments of the inventive concept, a silicon-containing film including few impurities may be provided because non-volatile by-products are not generated. Furthermore, the silicon compound of General formula (1) may have a relatively high content of silicon atoms per molecule, and thus, the silicon compound of General formula (1) may provide a relatively high deposition rate during the process of forming the silicon-containing film.

In addition, the silicon compound according to some embodiments may have excellent thermal stability and high durability. In particular, the silicon compound of General formula (1) may have a structure including a *—Si—Se—* bonding unit (* is a bonding site). Thus, in a deposition process for forming a silicon-containing film using the silicon compound of General formula (1), Si—Se bonds included in the silicon compound of General formula (1) may be decomposed to form selenol. Because selenol is highly volatile, selenol may be relatively easily removed during the deposition process for forming the silicon-containing film. Accordingly, selenium (Se) atoms included in the silicon compound of General formula (1) may not remain in the silicon-containing film. Therefore, a silicon-containing film that may not include Se atoms may be formed. As a result, a high-purity silicon-containing film including few impurities may be obtained.

In addition, the silicon compound according to some embodiments may be liquid at room temperature and normal pressure (1 atm). Accordingly, the silicon compound according to some embodiments may have sufficient volatility to be used in a deposition process, may have excellent thermal stability, may be easy to handle and transport, and may form a high-quality silicon-containing film with high productivity.

A method of preparing the silicon compounds according to some embodiments, is not specifically limited, and the silicon compound may be prepared by using organic chemical reactions known in the art.

The silicon compound according to some embodiments may be used as a source appropriate for a chemical vapor deposition (CVD) process or an atomic layer deposition (ALD) process. For example, the silicon compound according to some embodiments may be used as a source appropriate for a metal organic CVD (MOCVD) process, a low-pressure CVD (LPCVD) process, a plasma-enhanced CVD (PECVD) process, or a plasma-enhanced ALD (PEALD) process, without being limited thereto.

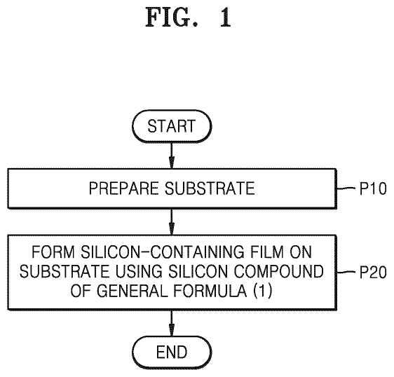

FIG. 1 is a flowchart of a method of manufacturing an IC device, according to some embodiments of the inventive concept.

Referring to FIG. 1, in process P10, a substrate may be prepared.

The substrate may include a material selected from a semiconductor substrate, a silicon-on insulator (SOI) substrate, quartz, glass, plastic, a metal-containing film, an insulating film, and a combination thereof. For example, the semiconductor substrate may include a material selected from silicon (Si), germanium (Ge), silicon germanium (SiGe), gallium phosphide (GaP), gallium arsenide (GaAs), silicon carbide (SiC), silicon germanium carbide (SiGeC), indium arsenide (InAs), indium phosphide (InP), and a combination thereof, without being limited thereto. The plastic may include a material selected from polyimide, polyethylene terephthalate (PET), polyethylene naphthalate (PEN), poly methyl methacrylate (PMMA), polycarbonate (PC), polyether sulfone (PES), polyester, and a combination thereof, without being limited thereto. The metal-containing film may include titanium (Ti), titanium nitride (TiN), tantalum (Ta), tantalum nitride (TaN), cobalt (Co), ruthenium (Ru), zirconium (Zr), hafnium (Hf), lanthanum (La), tungsten (W), or a combination thereof, without being limited thereto. The substrate may include silicon nitride, titanium nitride, tantalum nitride, silicon oxide, niobium oxide, zirconium oxide, hafnium oxide, lanthanum oxide, or a combination thereof.

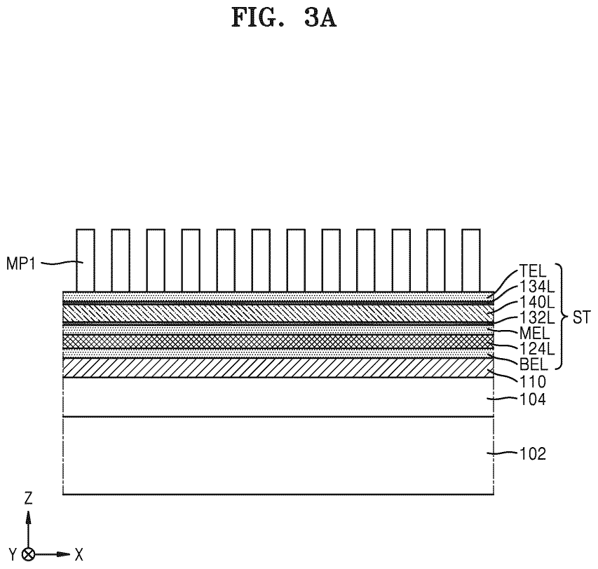

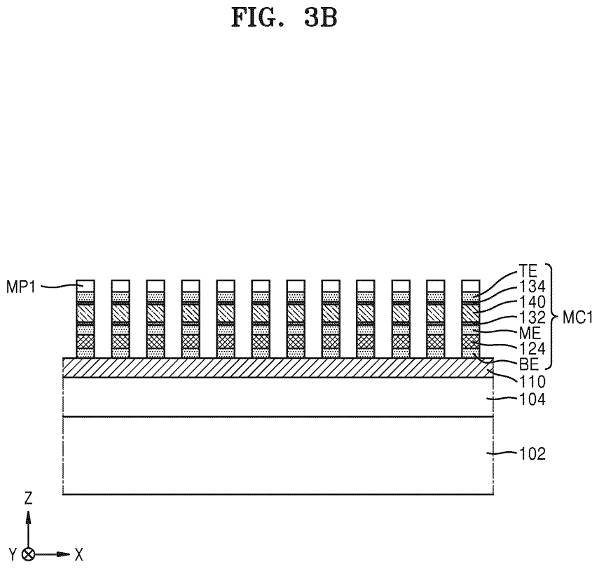

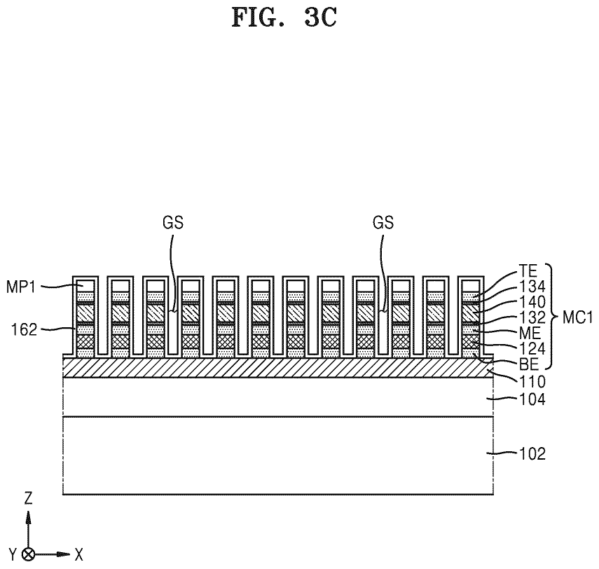

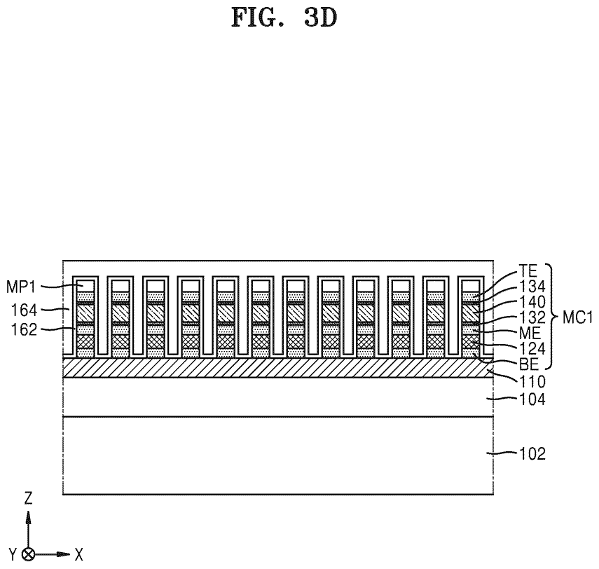

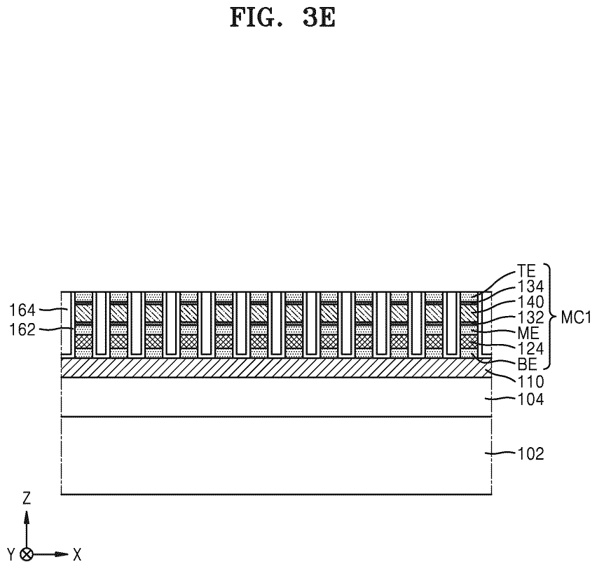

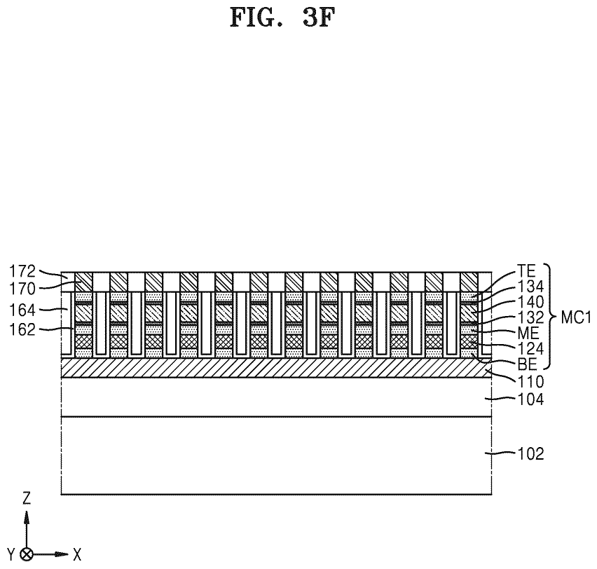

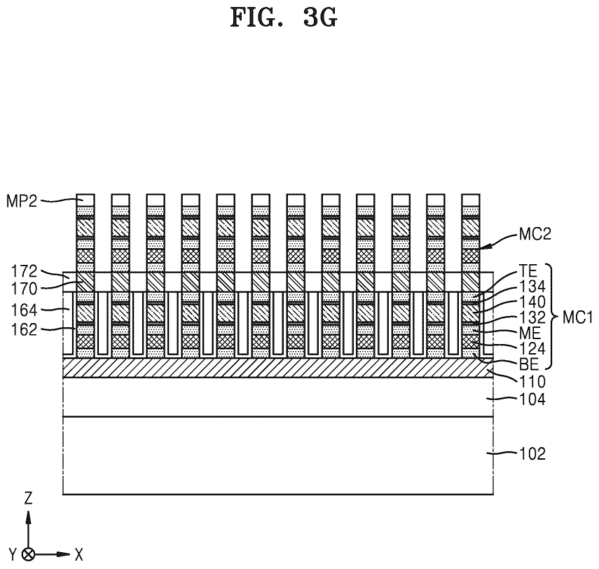

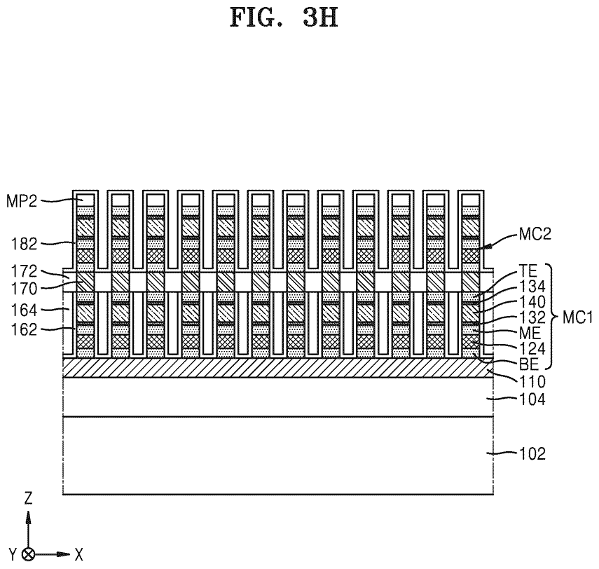

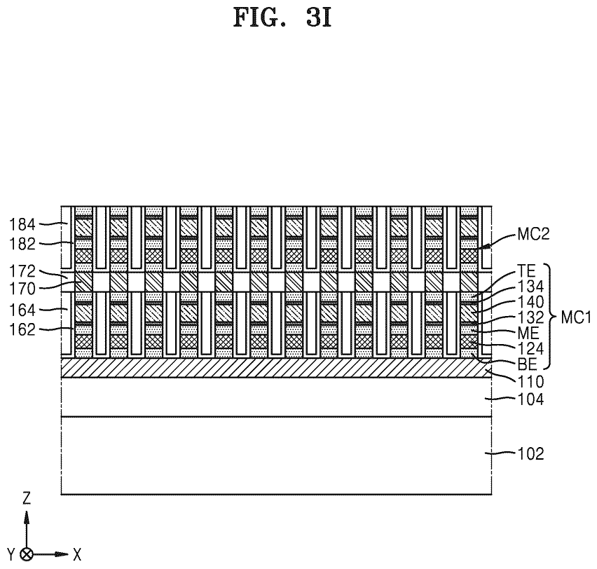

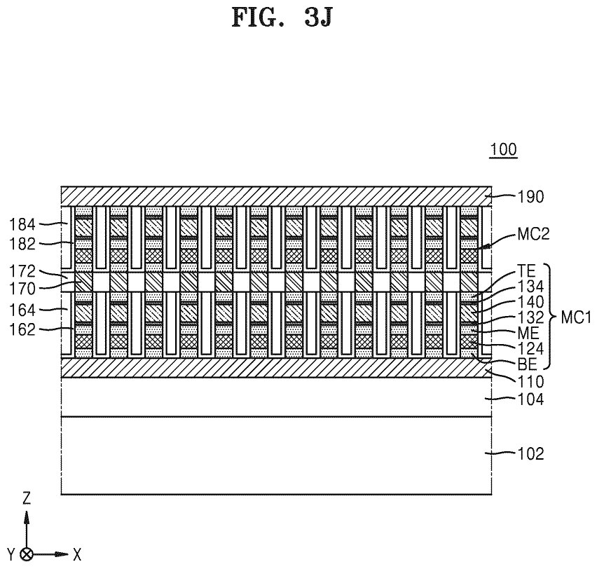

In example embodiments, the substrate may have the same configuration as a substrate 102 that will be described below with reference to FIG. 3A.

In process P20 of FIG. 1, a silicon-containing film may be formed on the substrate by using a composition for forming a silicon-containing film including the silicon compound of General formula (1).

The composition for forming the silicon-containing film may include at least one silicon compound according to some embodiments of the inventive concept. In example embodiments, the composition for forming the silicon-containing film may include at least one of the silicon compounds represented by Formulae 1 to 20. In example embodiments, the silicon compound may be liquid at room temperature.

In example embodiments, the composition for forming the silicon-containing film may include a mixture of at least two compounds selected from the silicon compounds represented by Formulae 1 to 20.

The silicon-containing film, which may be formed using the method of manufacturing the IC device according to some embodiments of the inventive concept, may include a silicon film, a silicon oxide (SiO₂) film, a silicon oxycarbide (SiOC) film, a silicon nitride (SiN) film, a silicon oxynitride (SiON) film, a silicon carbonitride (SiCN) film, and/or a silicon carbide (SiC) film, without being limited thereto.

In other example embodiments, the silicon-containing film to be formed may further include a metal. When the silicon-containing film to be formed is a film including a metal, the composition for forming the silicon-containing film may include a compound (referred to as the term “another precursor” hereinafter) including a predetermined metal, in addition to the silicon compound according to some embodiments of the inventive concept. For example, the other precursor may include lithium (Li), sodium (Na), potassium (K), magnesium (Mg), calcium (Ca), strontium (Sr), barium (Ba), titanium (Ti), tantalum (Ta), niobium (Nb), vanadium (V), zirconium (Zr), hafnium (Hf), chromium (Cr), molybdenum (Mo), tungsten (W), manganese (Mn), iron (Fe), cobalt (Co), rhodium (Rh), iridium (Ir), nickel (Ni), palladium (Pd), platinum (Pt), copper (Cu), silver (Ag), gold (Au), zinc (Zn), aluminum (Al), gallium (Ga), indium (In), germanium (Ge), tin (Sn), lead (Pb), antimony (Sb), bismuth (Bi), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu), but the inventive concept is not limited to the elements described above.

In yet other example embodiments, the composition for forming the silicon-containing film may further include an organic solvent in addition to the silicon compound according to some embodiments of the inventive concept. The organic solvents are not limited to specific kinds and may be known organic solvents. For example, the organic solvents may be acetate esters such as ethyl acetate, n-butyl acetate, and methoxyethyl acetate; ethers such as tetrahydrofuran, tetrahydropyran, ethylene glycol dimethyl ether, diethylene glycol dimethyl ether, triethylene glycol dimethyl ether, and dibutyl ether; ketones such as methyl butyl ketone, methyl isobutyl ketone, ethyl butyl ketone, dipropyl ketone, diisobutyl ketone, methyl amyl ketone, cyclohexanone, and methyl cyclohexanone; hydrocarbons such as hexane, cyclohexane, dimethylcyclohexane, ethylcyclohexane, heptane, octane, toluene, and xylene; hydrocarbons having a cyano group such as cyanopropane, 1-cyanobutane, 1-cyanohexane, cyanocyclohexane, cyanobenzene, 1,3-dicyanopropane, 1,4-dicyanobutane, 1,6-dicyanohexane, 1,4-dicyanocyclohexane, and 1,4-dicyanobenzene; pyridine; and/or lutidine. The above-described organic solvents may be used alone or in a mixture of at least two kinds thereof considering the solubilities, use temperatures, boiling points, and ignition points of solutes.

To form the silicon-containing film according to process P20 of FIG. 1, a CVD process or an ALD process may be employed. The composition for forming the silicon-containing film including the silicon compound according to some embodiment may be suitably used for chemical deposition processes, such as a CVD process or an ALD process.

In example embodiments, when the composition for forming the silicon-containing film is introduced into a deposition system, the composition for forming the silicon-containing film may be put into a vapor state by vaporization and may be introduced together with a carrier gas (e.g., argon, nitrogen, and helium) used as needed into a reaction chamber in which a substrate is loaded. In other example embodiments, when the composition for forming the silicon-containing film is introduced into the deposition system, the composition for forming the silicon-containing film may be conveyed in a liquid state or a solution state to a vaporizer, heated and/or depressurized and vaporized in the vaporizer to be put into a vapor state, and then introduced into the reaction chamber.

The process of forming the silicon-containing film according to process P20 of FIG. 1 may include a process of vaporizing the composition for forming the silicon-containing film including the silicon compound of General formula (1) and introducing the vaporized composition into the reaction chamber in which the substrate is loaded, and depositing the silicon compound on a surface of the substrate to form a silicon precursor thin film on the substrate, and a process of causing a reaction of the silicon precursor thin film with a reactive gas to form the silicon-containing film on the surface of the substrate.

The reactive gas may be a gas that reacts with the precursor thin film. For example, the reactive gas may be an oxidizing gas, a reducing gas, or a nitriding gas.

The oxidizing gas may be selected from O₂, O₃, O₂ plasma, H₂O, NO₂, NO, N₂O (nitrous oxide), CO, CO₂, H₂O₂, HCOOH, CH₃COOH, (CH₃CO)₂O, alcohol, peroxide (peroxide), sulfur oxide, and a combination thereof.

The reducing gas may be H₂.

The nitriding gas may be selected from NH₃, N₂ plasma, an organic amine compound (e.g., monoalkylamine, dialkylamine, trialkylamine, and alkylene diamine), a hydrazine compound, and a combination thereof.

When a silicon oxide film is formed in process P20 of FIG. 1, the oxidizing gas may be used as the reactive gas. When a silicon nitride film is formed in process P20 of FIG. 1, the nitriding gas may be used as the reactive gas.

In example embodiments, in process P20 of FIG. 1, the silicon-containing film may be formed by using a thermal CVD process of forming a thin film by reacting a source gas including the silicon compound according to some embodiments or both the source gas and a reactive gas due to only heat, a plasma CVD process using heat and plasma, a photo-CVD process using heat and light, a photo-plasma CVD process using heat, light, and plasma, or an ALD process.

During the formation of the silicon-containing film according to process P20 of FIG. 1, deposition conditions may be controlled based on a desired thickness and type of silicon-containing film and thermal characteristics of the silicon compound used as a source. In example embodiments, the deposition conditions may include a flow rate at which the composition for forming the silicon-containing film is injected, a flow rate of the carrier gas is injected, a flow rate at which the reactive gas is injected, pressure, radio-frequency (RF) power, a reaction temperature (substrate temperature), and the like.

In example embodiments, the composition for forming the silicon-containing film may be injected at a flow rate of about 10 cc/min to about 1000 cc/min. The carrier gas may be injected at a flow rate of about 10 cc/min to about 1000 cc/min. The reactive gas may be injected at a flow rate of about 1 cc/min to about 1000 cc/min. The pressure may be in a range of about 0.5 torr to about 10 torr. The RF power may be in a range of about 100 W to about 1000 W. The reaction temperature (or a substrate temperature) may be a temperature at which the silicon compound may sufficiently react. For example, the reaction temperature may be in a range of about 30° C. to about 400° C. (e.g., a range of about 100° C. to about 350° C. or a range of about 100° C. to about 250° C.). However, the deposition conditions are not limited to the examples described above.

The silicon compound according to some embodiments of the inventive concept may be relatively highly reactive and volatile. Accordingly, a silicon-containing film of good quality may be formed using the silicon compound.

When the process of forming the silicon-containing film according to process P20 of FIG. 1 is performed using an ALD process, a film thickness of the silicon-containing film may be controlled by adjusting the number of cycles of the ALD process. The formation of the silicon-containing film on the substrate using the ALD process may include a process of introducing vapor formed by vaporizing a composition for forming a silicon-containing film, which includes the silicon compound according to some embodiments of the inventive concept, into the reaction chamber, a process of forming a silicon precursor thin film on the surface of the substrate by using the vapor, a process of exhausting unreacted source gases remaining on the substrate from a reaction space, and a process of forming the silicon-containing film on the surface of the substrate by causing a chemical reaction of the silicon precursor thin film with the reactive gas.

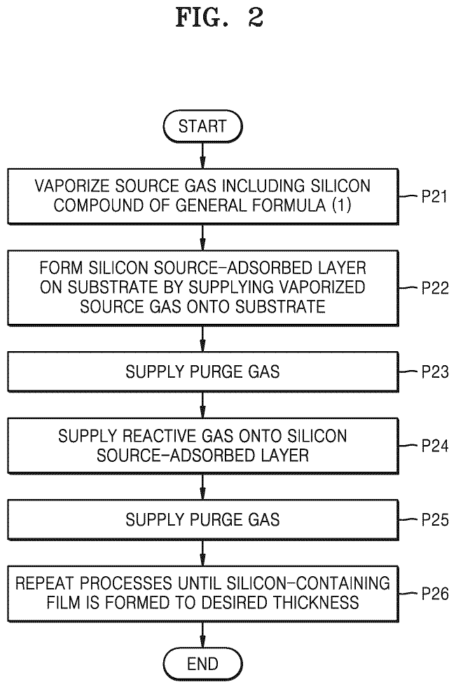

FIG. 2 is a flowchart of a method of forming a silicon-containing film of an IC device according to some embodiments of the inventive concept. A method of forming a silicon-containing film by using an ALD process according to process P20 of FIG. 1 will be described with reference to FIG. 2.

Referring to FIG. 2, in process P21, a source gas including a silicon compound having a structure of General formula (1) may be vaporized.

In example embodiments, the source gas may include a composition for forming the silicon-containing film described above. The process of vaporizing the source gas may be performed at a temperature of about 0° C. to about 200° C. When the source gas is vaporized, inner pressure of the source container or the vaporizer may be in a range of about 1 Pa to about 10,000 Pa.

In process P22 of FIG. 2, the source gas vaporized according to process P21 may be supplied onto a substrate, and thus, a silicon source-adsorbed layer may be formed on the substrate. In this case, a reaction temperature may be selected in a range of about 30° C. to about 400° C. (e.g., a range of about 100° C. to about 350° C. or a range of about 100° C. to about 250° C.) without being limited thereto. A reaction pressure may be in a range of about 1 Pa to about 10,000 Pa (e.g., about 10 Pa to about 1,000 Pa) without being limited thereto.

By supplying the vaporized source gas onto the substrate, an adsorbed layer including a chemisorbed layer and a physisorbed layer of the vaporized source gas may be formed on the substrate. The chemisorbed layer of the vaporized source gas may constitute the silicon source adsorption layer.

In process P23 of FIG. 2, by-products on the substrate may be removed by supplying a purge gas onto the substrate. For example, an inert gas, such as argon (Ar), helium (He), and neon (Ne), or nitrogen (N₂) gas may be used as the purge gas.

In other example embodiments, instead of the purge gas, a reaction space in which the substrate is loaded may be exhausted by reducing pressure of the reaction space. In this case, to reduce the pressure of the reaction space, the reaction space may be maintained under pressure of about 0.01 Pa to about 300 Pa (e.g., about 0.01 Pa to about 100 Pa).

In example embodiments, a process of heating the substrate on which the silicon source-adsorbed layer is formed or a process of annealing a reaction chamber containing the substrate may be further performed. The annealing process may be performed at room temperature to a temperature of about 500° C., in one example, at a temperature of about 50° C. to about 400° C.

In process P24 of FIG. 2, a reactive gas may be supplied onto the silicon source-adsorbed layer formed on the substrate, and thus, a silicon-containing film may be formed on an atomic level.

In example embodiments, when a silicon oxide film is formed on the substrate, the reactive gas may be an oxidizing gas selected from O₂, O₃, O₂ plasma, H₂O, NO₂, NO, nitrous oxide (N₂O), CO, CO₂, H₂O₂, HCOOH, CH₃COOH, (CH₃CO)₂O, alcohol, peroxide, sulfur oxide, and a combination thereof.

In other example embodiments, when a silicon nitride layer is formed on the substrate, the reactive gas may be a nitriding gas selected from NH₃, N₂ plasma, an organic amine compound (e.g., monoalkylamine, dialkylamine, trialkylamine, and alkylene diamine), a hydrazine compound, and a combination thereof.

In yet other example embodiments, the reactive gas may be a reducing gas (e.g., H₂).

In process P24 of FIG. 2, the reaction space may be maintained at room temperature to a temperature of about 500° C. (e.g., at a temperature of about 100° C. to about 350° C. or a temperature of about 100° C. to about 250° C.) such that the silicon source-adsorbed layer may sufficiently react with the reactive gas. In process P24, pressure of the reaction space may range from about 1 Pa to about 10,000 Pa (e.g., about 10 Pa to about 1,000 Pa).

In process P24 of FIG. 2, the reactive gas may be processed with plasma. During the plasma processing process, an RF output may range from about 0 W to about 1,500 W (e.g., about 50 W to about 600 W).

In process P25 of FIG. 2, by-products remaining on the substrate may be removed by supplying a purge gas onto the substrate. For example, an inert gas, such as argon (Ar), helium (He), and neon (Ne), or nitrogen (N₂) gas may be used as a purge gas.

In process P26 of FIG. 2, processes P21 to P25 of FIG. 2 may be repeated until the silicon-containing film has a desired thickness.

A thin-film deposition process including a series of processes, that is, processes P21 to P25 of FIG. 2, may be defined as one cycle, and the cycle may be repeated a plurality of times until the silicon-containing film is has a desired thickness. In example embodiments, after the cycle is performed once, unreacted gases may be exhausted from the reaction chamber by performing an exhaust process using a purge gas, which is similar to that of process P23 or P25, and subsequent cycles may be then performed.

The method of forming the silicon-containing film, which has been described with reference to FIG. 2, is merely an example, and various modifications and changes of the method may be made without departing from the scope of the inventive concept.

For example, to form the silicon-containing film on the substrate, the silicon compound having a structure of General formula (1) and at least one of another precursor, a reactive gas, a carrier gas, and a purge gas may be simultaneously or sequentially supplied onto the substrate. Details of the other precursor, the reactive gas, the carrier gas, and the purge gas, which may be supplied onto the substrate together with the silicon compound represented by General formula (1), are as described above.

In other example embodiments, in the process of forming the silicon-containing film, which has been described with reference to FIG. 2, a process of supplying the reactive gas onto the substrate between processes P21 to P25 may be further performed.

According to some embodiments, when a silicon-containing film is formed using an ALD process, energy (e.g., plasma, light, and a voltage) may be applied. A time period for which the energy is applied may be variously selected. For example, the energy (e.g., plasma, light, and a voltage) may be applied when a source gas including the silicon compound according to some embodiments is introduced into a reaction chamber, when the source gas is adsorbed on the substrate, when an exhaust process is performed using the purge gas, when the reactive gas is introduced into the reaction chamber, or between respective time periods for which the processes described above are performed.

According to some embodiments, after the silicon-containing film is formed using the silicon compound of General formula (1), a process of annealing the silicon-containing film in an inert atmosphere, an oxidizing atmosphere, or a reducing atmosphere may be further performed. The annealing process may be performed under temperature conditions selected in a range of about 200° C. to about 1,000° C. (e.g., about 250° C. to about 500° C.), but the inventive concept is not limited thereto.

The silicon-containing film formed using the processes described with reference to FIGS. 1 and 2 may include a silicon film, a silicon oxide (SiO₂) film, a silicon oxycarbide (SiOC) film), a silicon nitride (SiN) film, a silicon oxynitride (SiON) film, a silicon carbonitride (SiCN) film, and/or a silicon carbide (SiC) film, without being limited thereto.

The silicon-containing film formed using the method according to some embodiments may be used as a material for various components included in an IC device. For example, the silicon-containing film may be used as a material for an insulating film that is included in a logic device or a memory device. The logic device may include a central processing unit (CPU), a controller, and/or an application specific integrated circuit (ASIC). The memory device may include a volatile memory device, such as dynamic random access memory (DRAM) and static RAM (SRAM), or a non-volatile memory device, such as phase-change RAM (PRAM), magnetoresistive RAM (MRAM), ferroelectric RAM (FeRAM), and resistive RAM (RRAM). However, the use of the silicon-containing film is not limited to the examples described above.

FIGS. 3A to 3J are cross-sectional views illustrating a method of manufacturing an IC device (e.g., an IC device 100 in FIG. 3J) according to some embodiments of the inventive concept. Referring to FIG. 3A, an interlayer insulating film 104 may be formed on a substrate 102.

The substrate 102 may include a semiconductor substrate. For example, the substrate 102 may include silicon (Si), germanium (Ge), or silicon germanium (SiGe). The interlayer insulating film 104 may include, for example, an oxide film, a nitride film, or a combination thereof. The interlayer insulating film 104 may electrically isolate unit elements, which are included in the plurality of circuits formed on the substrate 102, from each other as needed. Although FIG. 3A illustrates an example in which the interlayer insulating film 104 is on the substrate 102, the inventive concept is not limited thereto. For example, an IC layer may be between the substrate 102 and the interlayer insulating film 104. The IC layer may include a peripheral circuit for operations of a plurality of memory cells formed on the interlayer insulating film 104 and/or a core circuit for calculations.

A plurality of first conductive lines 110 may be formed on the interlayer insulating film 104. The plurality of first conductive lines 110 may each extend longitudinally in a first direction (e.g., X direction) and may be parallel to each other. Although one first conductive line 110 is illustrated in FIG. 3A, the plurality of first conductive lines 110 may be repeatedly arranged apart from each other in a second direction (e.g., Y direction) on the substrate 102. Respective spaces between the plurality of first conductive lines 110 may be filled with insulating lines (not shown). The insulating line may include, for example, a silicon oxide film, a silicon nitride film, or a combination thereof. The first direction and the second direction may be parallel to an upper surface of the substrate 102 that faces the interlayer insulating film 104 and may be a first horizontal direction and a second horizontal direction, respectively.

The plurality of first conductive lines 110 may include a metal, a conductive metal nitride, a conductive metal oxide, or a combination thereof. In example embodiments, the plurality of first conductive lines 110 may include, for example, tungsten (W), titanium (Ti), tantalum (Ta), aluminum (Al), copper (Cu), carbon (C), carbon nitride (CN), titanium nitride (TiN), titanium aluminum nitride (TiAlN), titanium silicon nitride (TiSiN), titanium carbonitride (TiCN), titanium carbon silicon nitride (TiCSiN), tungsten nitride (WN), cobalt silicon nitride (CoSiN), tungsten silicon nitride (WSiN), tantalum nitride (TaN), tantalum carbonitride (TaCN), tantalum silicon nitride (TaSiN), gold (Au), silver (Ag), iridium (Ir), platinum (Pt), palladium (Pd), ruthenium (Ru), zirconium (Zr), rhodium (Rh), nickel (Ni), cobalt (Co), chromium (Cr), tin (Sn), zinc (Zn), indium tin oxide (ITO), an alloy thereof, or a combination thereof. Each of the plurality of first conductive lines 110 may further include a conductive barrier film. The conductive barrier film may include, for example, Ti, TiN, Ta, TaN, or a combination thereof.

A stack structure ST in which a lower electrode layer BEL, a selection device layer 124L, a middle electrode layer MEL, a lower barrier layer 132L, a resistive memory layer 140L, an upper barrier layer 134L, and an upper electrode layer TEL are sequentially stacked may be formed on the plurality of first conductive lines 110, and a first mask pattern MP1 may be then formed on the stack structure ST.

Each of the lower electrode layer BEL, the middle electrode layer MEL, and the upper electrode layer TEL may include a conductive material, for example, W, Ti, Ta, Al, Cu, C, CN, TiN, TiAlN, TiSiN, TiCN, TiCSiN, WN, CoSiN, WSiN, TaN, TaCN, TaSiN, or a combination thereof, without being limited thereto.

The selection device layer 124L may include a chalcogenide switching material that is in an amorphous phase. The selection device layer 124L may include an ovonic threshold switching (OTS) material. The OTS material may include a chalcogenide switching material. In example embodiments, the selection device layer 124L may include a single layer or a multilayered film including at least one material selected from binary materials (e.g., GeSe, GeS, AsSe, AsTe, AsS, SiTe, SiSe, SiS, GeAs, SiAs, SnSe, and SnTe), ternary materials (e.g., GeAsTe, GeAsSe, AlAsTe, AlAsSe, SiAsSe, SiAsTe, GeSeTe, GeSeSb, GaAsSe, GaAsTe, InAsSe, InAsTe, SnAsSe, and SnAsTe), quaternary materials (e.g., GeSiAsTe, GeSiAsSe, GeSiSeTe, GeSeTeSb, GeSiSeSb, GeSiTeSb, GeSeTeBi, GeSiSeBi, GeSiTeBi, GeAsSeSb, GeAsTeSb, GeAsTeBi, GeAsSeBi, GeAsSeIn, GeAsSeGa, GeAsSeAl, GeAsSeTl, GeAsSeSn, GeAsSeZn, GeAsTeIn, GeAsTeGa, GeAsTeAl, GeAsTeTl, GeAsTeSn, and GeAsTeZn), quinary materials (e.g., GeSiAsSeTe, GeAsSeTeS, GeSiAsSeS, GeSiAsTeS, GeSiSeTeS, GeSiAsSeP, GeSiAsTeP, GeAsSeTeP, GeSiAsSeIn, GeSiAsSeGa, GeSiAsSeAl, GeSiAsSeTl, GeSiAsSeZn, GeSiAsSeSn, GeSiAsTeIn, GeSiAsTeGa, GeSiAsTeAl, GeSiAsTeTl, GeSiAsTeZn, GeSiAsTeSn, GeAsSeTeIn, GeAsSeTeGa, GeAsSeTeAl, GeAsSeTeTl, GeAsSeTeZn, GeAsSe TeSn, GeAsSeSIn, GeAsSeSGa, GeAsSeSAl, GeAsSeSTl, GeAsSeSZn, GeAsSeSSn, GeAsTeSIn, GeAsTeSGa, GeAsTeSAl, GeAsTeSTl, GeAsTeSZn, GeAsTeSSn, GeAsSeInGa, GeAsSeInAl, GeAsSeInTl, GeAsSeInZn, GeAsSeInSn, GeAsSeGaAl, GeAsSeGaTl, GeAsSeGaZn, GeAsSeGaSn, GeAsSeAlTl, GeAsSeAlZn, GeAsSEAlSn, GeAsSeTlZn, GeAsSeTlSn, and GeAsSeZnSn), and senary materials (e.g., GeSiAsSeTeS, GeSiAsSeTeIn, GeSiAsSeTeGa, GeSiAsSeTeAl, GeSiAsSeTeTl, GeSiAsSeTeZn, GeSiAsSeTeSn, GeSiAsSeTeP, GeSiAsSeSIn, GeSiAsSeSGa, GeSiAsSeSAl, GeSiAsSeSTl, GeSiAsSeSZn, GeSiAsSeSSn, GeAsSeTeSIn, GeAsSeTeSGa, GeAsSeTeSAl, GeAsSeTeSTl, GeAsSeTeSZn, GeAsSeTeSSn, GeAsSeTePIn, GeAsSeTePGa, GeAsSeTePAl, GeAsSeTePTl, GeAsSeTePZn, GeAsSeTePSn, GeSiAsSeInGa, GeSiAsSeInAl, GeSiAsSeInTl, GeSiAsSeInZn, GeSiAsSeInSn, GeSiAsSeGaAl, GeSiAsSeGaTl, GeSiAsSeGaZn, GeSiAsSeGaSn, GeSiAsSeAlSn, GeAsSeTeInGa, GeAsSeTeInAl, GeAsSeTeInTl, GeAsSeTeInZn, GeAsSeTeInSn, GeAsSeTeGaAl, GeAsSeTeGaTl, GeAsSeTeGaZn, GeAsSeTeGaSn, GeAsSeTeAlSn, GeAsSeSInGa, GeAsSeSInAl, GeAsSeSInTl, GeAsSeSInZn, GeAsSeSInSn, GeAsSeSGaAl, GeAsSeSGaTl, GeAsSeSGaZn, GeAsSeSGaSn, and GeAsSeSAlSn).

In other example embodiments, the selection device layer 124L may include at least one material, which is selected from the binary to senary materials described above as examples of materials included in the selection device layer 124L, and at least one additional element selected from boron (B), carbon (C), nitrogen (N), and oxygen (O).

The resistive memory layer 140L may include a phase-change material of which a phase is reversibly changed between an amorphous state and a crystalline state according to a heating time. In example embodiments, the resistive memory layer 140L may include a chalcogenide material as a phase-change material. In example embodiments, the resistive memory layer 140L may include a single layer or a multilayered film including at least one material selected from binary materials (e.g., GeTe, GeSe, GeS, SbSe, SbTe, SbS, SbSe, SnSb, InSe, InSb, AsTe, AlTe, GaSb, AlSb, BiSb, ScSb, Ysb, CeSb, DySb, and NdSb), ternary materials (e.g., GeSbSe, AlSbTe, AlSbSe, SiSbSe, SiSbTe, GeSeTe, InGeTe, GeSbTe, GeAsTe, SnSeTe, GeGaSe, BiSbSe, GaSeTe, InGeSb, GaSbSe, GaSbTe, InSbSe, InSbTe, SnSbSe, SnSbTe, ScSbTe, ScSbSe, ScSbS, YSbTe, YSbSe, YSbS, CeSbTe, CeSbSe, CeSbS, DySbTe, DySbSe, DySbS, NdSbTe, NdSbSe, and NdSbS), quaternary materials (e.g., GeSbTeS, BiSbTeSe, AgInSbTe, GeSbSeTe, GeSnSbTe, SiGeSbTe, SiGeSbSe, SiGeSeTe, BiGeSeTe, BiSiGeSe, BiSiGeTe, GeSbTeBi, GeSbSeBi, GeSbSeIn, GeSbSeGa, GeSbSeAl, GeSbSeTl, GeSbSeSn, GeSbSeZn, GeSbTeIn, GeSbTeGa, GeSbTeAl, GeSbTeTl, GeSbTeSn, GeSbTeZn, ScGeSbTe, ScGeSbSe, ScGeSbS, YGeSbTe, YGeSbSe, YGeSbS, CeGeSbTe, CeGeSbSe, CeGeSbS, DyGeSbTe, DyGeSbSe, DyGeSbS, NdGeSbTe, NdGeSbSe, and NdGeSbS), and quinary materials (e.g., InSbTeAsSe, GeScSbSeTe, GeSbSeTeS, GeScSbSeS, GeScSbTeS, GeScSeTeS, GeScSbSeP, GeScSbTeP, GeSbSeTeP, GeScSbSeIn, GeScSbSeGa, GeScSbSeAl, GeScSbSeTl, GeScSbSeZn, GeScSbSeSn, GeScSbTeIn, GeScSbTeGa, GeSbAsTeAl, GeScSbTeTl, GeScSbTeZn, GeScSbTeSn, GeSbSeTeIn, GeSbSeTeGa, GeSbSeTeAl, GeSbSeTeTl, GeSbSeTeZn, GeSbSeTeSn, GeSbSeSIn, GeSbSeSGa, GeSbSeSAl, GeSbSeSTl, GeSbSeSZn, GeSbSeSSn, GeSbTeSIn, GeSbTeSGa, GeSbTeSAl, GeSbTeSTl, GeSbTeSZn, GeSbTeSSn, GeSbSeInGa, GeSbSeInAl, GeSbSeInTl, GeSbSeInZn, GeSbSeInSn, GeSbSeGaAl, GeSbSeGaTl, GeSbSeGaZn, GeSbSeGaSn, GeSbSeAlTl, GeSbSeAlZn, GeSbSeAlSn, GeSbSeTlZn, GeSbSeTlSn, and GeSbSeZnSn).

In other example embodiments, the resistive memory layer 140L may include at least one material, which is selected from the binary to quinary materials described above as examples of materials included in the resistive memory layer 140L, and at least one additional element selected from boron (B), carbon (C), nitrogen (N), oxygen (O), phosphorus (P), cadmium (Cd), tungsten (W), titanium (Ti), hafnium (Hf), and zirconium (Zr).

Each of the lower barrier layer 132L and the upper barrier layer 134L may include a conductive material, for example, tungsten (W), tungsten nitride (WN), tungsten carbide (WC), or a combination thereof, without being limited thereto.

The first mask pattern MP1 may be formed to have a planar shape having a plurality of island patterns. In example embodiments, the first mask pattern MP1 may include a hard mask including an oxide film, a nitride film, or a combination thereof. In example embodiments, to form the first mask pattern MP1, a photolithography process using extreme ultraviolet (EUV) (13.5 nm), krypton fluoride (KrF) excimer laser (248 nm), argon fluoride (ArF) excimer laser (193 nm), or fluorine (F₂) excimer laser (157 nm) may be used as a light source.

Referring to FIG. 3B, the stack structure ST may be etched using the first mask pattern MP1 as an etch mask. Thus, a plurality of first level memory cells MC1, each of which includes a lower electrode BE, a selective device 124, a middle electrode ME, a lower barrier 132, a resistive memory pattern 140, an upper barrier 134, and an upper electrode TE, may be formed on the plurality of first conductive lines 110.

During the etching of the stack structure ST, a thickness of the first mask pattern MP1 may be reduced by consuming a portion of the first mask pattern MP1.

Referring to FIG. 3C, a silicon-containing insulating liner 162 covering a sidewall of each of the plurality of first level memory cells MC1 may be formed on the resultant structure of FIG. 3B.

The silicon-containing insulating liner 162 may be formed to conformally cover exposed surfaces of the plurality of first level memory cells MC1.

The silicon-containing insulating liner 162 may be formed using an ALD process. In example embodiments, to form the silicon-containing insulating liner 162, a silicon-containing film may be formed using process P20 of FIG. 1 or the method described with reference to FIG. 2. In example embodiments, the silicon-containing insulating liner 162 may include a silicon nitride film.

A process temperature for forming the silicon-containing insulating liner 162 may be in a range of about 30° C. to about 400° C. (e.g., a range of about 100° C. to about 350° C. or a range of about 100° C. to about 250° C.). A lower process temperature for forming the silicon-containing insulating liner 162 may be advantageous in reducing or preventing deterioration of a plurality of resistive memory patterns 140 during the formation of the silicon-containing insulating liner 162.

After the silicon-containing insulating liner 162 is formed, gap-fill spaces GS may be respectively left between the plurality of first level memory cells MC1.

Referring to FIG. 3D, a gap-fill insulating film 164 may be formed on the resultant structure of FIG. 3C. The gap-fill insulating film 164 may be formed to such a sufficient thickness as to cover the gap-fill spaces (e.g., GS in FIG. 3C) between the plurality of first level memory cells MC1 and respective top surfaces of the plurality of first level memory cells MC1.

Referring to FIG. 3E, the resultant structure of FIG. 3D may be planarized to expose a plurality of upper electrodes TE. As a result, the first mask pattern MP1 may be removed, and a height of each of the silicon-containing insulating liner 162 and the gap-fill insulating film 164 may be reduced.

Referring to FIG. 3F, a plurality of second conductive lines 170 may be formed to be spaced apart from each other on the resultant structure of FIG. 3E. The plurality of second conductive lines 170 may each extend longitudinally in the second direction (e.g., Y direction) and arranged parallel to each other. In the first direction (X direction), spaces between the plurality of second conductive lines 170 may be respectively filled with insulating lines 172.

A material of a plurality of second conductive lines 170 may be the same as that of the plurality of first conductive lines 110 described above. The insulating lines 172 may include, for example, a silicon oxide film, a silicon nitride film, or a combination thereof.

Referring to FIG. 3G, a plurality of second level memory cells MC2 may be formed on the plurality of second conductive lines 170 using the same method as the method of forming the plurality of first level memory cells MC1, which is described with reference to FIGS. 3A and 3B. However, to form the plurality of second level memory cells MC2, a second mask pattern MP2 may be used as an etch mask instead of the first mask pattern MP1. The second mask pattern MP2 may have substantially the same configuration as the first mask pattern MP1 described with reference to FIG. 3A. After the plurality of second level memory cells MC2 are formed, the second mask pattern MP2 may remain on the plurality of second level memory cells MC2.

Referring to FIG. 3H, a silicon-containing insulating liner 182 may be formed on the resultant structure of FIG. 3G to cover a sidewall of each of the plurality of second level memory cells MC2.

The silicon-containing insulating liner 182 may be formed to conformally cover exposed surfaces of the plurality of second level memory cells MC2.

In example embodiments, to form the silicon-containing insulating liner 182, a silicon-containing film may be formed using process P20 of FIG. 1 or the method described with reference to FIG. 2. In example embodiments, the silicon-containing insulating liner 182 may include a silicon nitride film. The silicon-containing insulating liner 182 may be formed using the same method as the method of forming the silicon-containing insulating liner 162, which is described with reference to FIG. 3C.

Referring to FIG. 3I, by using the same method as the method of forming the gap-fill insulating film 164, which is described with reference to FIGS. 3D and 3E, a gap-fill insulating film 184 may be formed on the silicon-containing insulating liner 182 to fill respective spaces of the plurality of second level memory cells MC2, and the obtained resultant structure may be then planarized. The gap-fill insulating film 184 may include, for example, a silicon oxide film, a silicon nitride film, or a combination thereof.

Referring to FIG. 3J, a plurality of third conductive lines 190 may be formed on the resultant structure of FIG. 3I. The plurality of third conductive lines 190 may each extend longitudinally in the first direction (e.g., X direction) and may be formed to be parallel to each other. Although one third conductive line 190 is illustrated in FIG. 3J, the plurality of third conductive lines 190 may be repeatedly formed to be spaced apart from each other in the second direction (e.g., Y direction) on the plurality of second level memory cells MC2. In the second direction (e.g., Y direction), spaces between the plurality of third conductive lines 190 may be filled with insulating lines (not shown). The insulating line may include, for example, a silicon oxide film, a silicon nitride film, or a combination thereof.

With a reduction in the design rule of the IC device 100, the plurality of first level memory cells MC1 may be arranged at a relatively small pitch, and the plurality of second level memory cells MC2 may be arranged at a relatively small pitch. Also, each of spaces between the plurality of first level memory cells MC1 and each of spaces between the plurality of second level memory cells MC2 may be relatively narrow and deep. To form the silicon-containing insulating liners 162 and 182 of high quality in three-dimensional, narrow, and deep spaces, an ALD process may be employed.

In the method of manufacturing the IC device, which is described with reference to FIGS. 3A to 3J, the silicon-containing insulating liners 162 and 182 may be formed using a silicon compound having a structure of General formula (1), thereby improving process stability. In addition, the silicon-containing insulating liners 162 and 182 having few impurities may be formed by using the silicon compound having the structure of General formula (1), and an ALD process may be performed at a relatively low temperature to form the silicon-containing insulating liners 162 and 182. Accordingly, during the formation of the silicon-containing insulating liners 162 and 182, degrade of the plurality of resistive memory patterns 140 may be reduced or prevented.

Next, specific examples of synthesizing a silicon compound and examples of forming a silicon-containing film, according to some embodiments, will be described. However, the inventive concept is not limited to the following examples.

In the following Synthesis examples, a known PEALD process was performed by using a 200-mm single-wafer-type deposition system (CN1, Atomic Premium) that was based on a commercially available shower head method. In addition, the thicknesses of silicon-containing films obtained in the following specific examples of forming silicon-containing films were measured using an ellipsometer (THERMA-WAVE Opti-probe 2600), and film properties of the obtained silicon-containing films were analyzed using X-ray photoelectron spectroscopy. Furthermore, wet etching resistances of the obtained silicon-containing films were estimated.

### SYNTHESIS EXAMPLE 1

### Synthesis of Compound (bis(dimethylsilyl)selenide) of Formula 1

250 g (2.65 mol) of chlorodimethylsilane and 477 g (6.62 mol) of tetrahydrofuran (THF) were put in a 2000-mL flask, which was flame dried in an anhydrous, inert atmosphere, and 165 g (1.32 mol) of sodium selenide (Na₂Se) was slowly added dropwise while being maintained at room temperature. After the addition was completed, the obtained solution was stirred at room temperature for about 6 hours to cause a reaction. The resultant sodium chloride salt (NaCl) was removed by filtration, and THF was removed under reduced pressure. 130 g (0.67 mol) of bis(dimethylsilyl)selenide was obtained from the recovered filtrate through distillation under reduced pressure (yield: 50%). It was confirmed that the obtained bis(dimethylsilyl)selenide was a liquid at a temperature of about 25° C.

1H-NMR (CDCl3): δ 0.50 (d, 12H (Si—CH₃), 4.66 (m, 2H (Si—H)

### SYNTHESIS EXAMPLE 2

### Synthesis of Compound (bis[(diisopropyl amino)methylsilyl]selenide) of Formula 9

200 g (1.74 mol) of dichloromethylsilane (CH₃SiHCl₂) and 1,800 g (26 mol) of n-pentane were put in a 5000-mL flask, which was flame dried in an anhydrous inert atmosphere. While being maintained at a temperature of about −25° C., 351.8 g (3.48 mol) of diisopropyl amine (NH(CH(CH₃)₂)₂) was slowly added, and the obtained solution was then stirred for about 6 hours and filtered to remove diisopropyl amine hydrogen chloride salt (HClNH(CH(CH₃)₂)₂) and pentane under reduced pressure. Thus, 252 g (1.40 mol) of a chloromethyldiisopropyl aminosilane (SiHClCH₃N(CH(CH₃)₂)₂) solution was recovered (yield: 81%). While stirring the recovered chloromethyldiisopropyl aminosilane solution with THF, 89 g (0.71 mol) of sodium selenide was slowly added at room temperature. After the addition was completed, the obtained solution was stirred at room temperature for about 6 hours to cause a reaction. The resultant sodium chloride salt (NaCl) was removed by filtration, and THF was removed under reduced pressure. 235 g (0.64 mol) of bis[(diisopropyl amino)methylsilyl]selenide was obtained from the recovered filtrate through distillation under reduced pressure (yield: 90%). It was confirmed that the obtained bis[(diisopropyl amino)methylsilyl]selenide was a liquid at a temperature of about 25° C.

1H-NMR (CDCl3): δ 0.55 (m, 6H (Si—CH₃), 1.10 (m, 24H (NCH(CH₃)₂), 3.26 (m, 4H (NCH(CH₃)₂), 5.26 (m, 2H, (Si—H))

### SYNTHESIS EXAMPLE 3

### Synthesis of Compound (bis(tert-butoxymethylsilyl)selenide) of Formula 12

150 g (1.34 mol) of dichloromethylsilane and 964 g (13.37 mol) of n-pentane were put in a 3000-mL flask, which was flame dried in an anhydrous inert atmosphere. While being maintained at a temperature of about −25° C., 150 g (1.34 mol) of potassium tert-butoxide (KOC(CH₃)₃) was slowly added, and the obtained solution was then stirred for about 6 hours and filtered to remove potassium chloride salt (KCl) and pentane under reduced pressure. Thus, 122.5 g (0.802 mol) of a chloromethyltert-butoxysilane (SiHClCH₃OC(CH₃)₃) solution was recovered (yield: 60%). While stirring the recovered chloromethyltert-butoxysilane solution with THF, 49.1 g (0.393 mol) of sodium selenide was slowly added at room temperature. After the addition was completed, the obtained solution was stirred at room temperature for about 6 hours to cause a reaction. The resultant sodium chloride salt (NaCl) was removed by filtration, and THE was removed under reduced pressure. 75.4 g (0.24 mol) of bis(tert-butoxymethylsilyl)selenide was obtained from the recovered filtrate through distillation under reduced pressure (yield: 60%). It was confirmed that the obtained bis(tert-butoxymethylsilyl)selenide was a liquid at a temperature of about 25° C.

1H-NMR (CDCl3): δ 0.59 (t, 6H (Si—CH₃), 1.31 (d, 18H (C(CH₃)₃), 5.53 (m, 2H (Si—H))

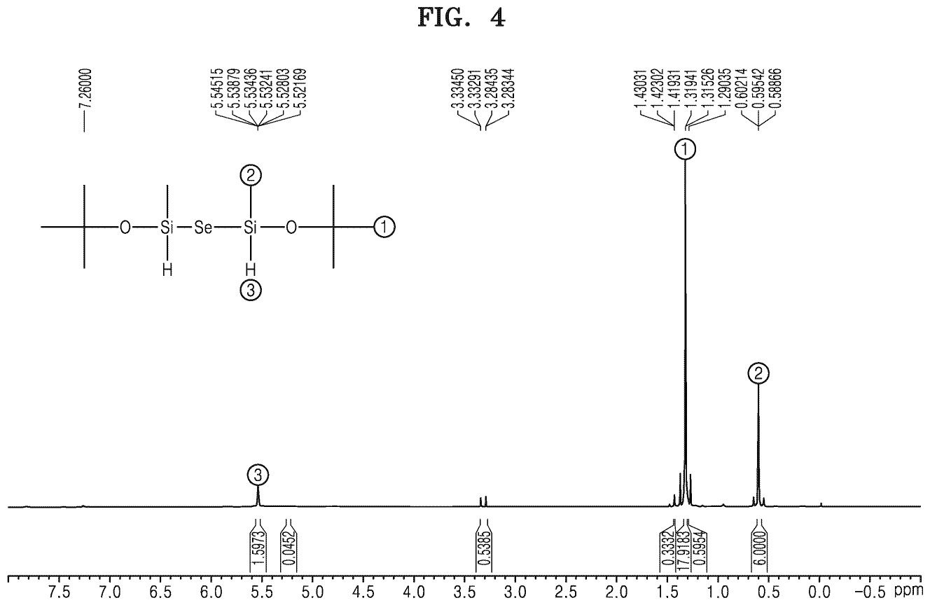

FIG. 4 is a graph showing nuclear magnetic resonance (NMR) spectrum of the silicon compound of Formula 12, which was synthesized in Synthesis example 3.

### COMPOUND ESTIMATION EXAMPLE 1

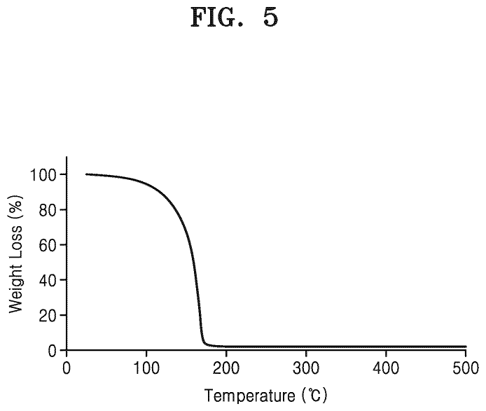

FIG. 5 is a graph showing thermogravimetric analysis (TGA) results of a compound of Formula 1, which was synthesized in Synthesis example 1.

### COMPOUND ESTIMATION EXAMPLE 2

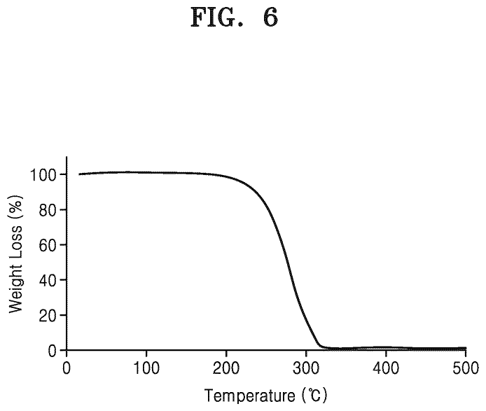

FIG. 6 is a graph showing TGA results of (bis[(diisopropyl amino)methylsilyl]selenide) that is the silicon compound of Formula 9, which was synthesized in Synthesis example 2.

### COMPOUND ESTIMATION EXAMPLE 3

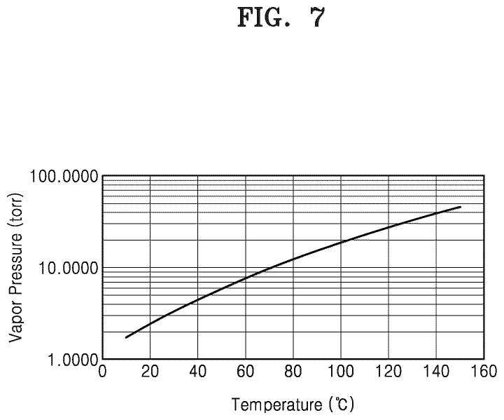

FIG. 7 is a graph showing the measurement results of vapor pressure of (bis(dimethylsilyl)selenide) that is the silicon compound of Formula 1, which was synthesized in Synthesis example 1.

### COMPOUND ESTIMATION EXAMPLE 4

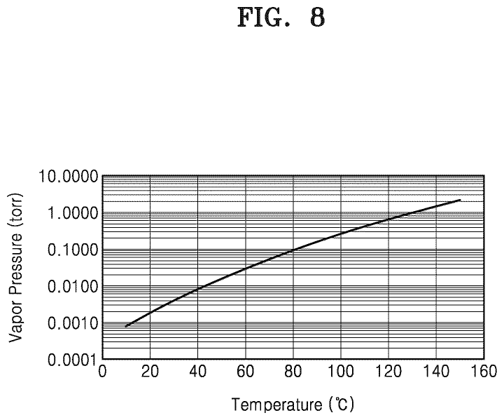

FIG. 8 is a graph showing the measurement results of vapor pressure of (bis[(diisopropyl amino)methylsilyl]selenide) that is the silicon compound of Formula 9, which was synthesized in Synthesis example 2.

From the results of FIGS. 5 to 8, it can be seen that the compounds of Formulae 1 and 10 have excellent vaporization properties.

### SILICON-CONTAINING FILM FORMATION EXAMPLE 1

### Formation of Silicon Nitride Film

A silicon nitride film was formed by a PEALD process using bis(dimethylsilyl)selenide, which was synthesized in Synthesis example 1, as a silicon precursor.

Conditions of the PEALD process for forming the silicon nitride film were as follows.

### Conditions

Reaction temperature (silicon substrate temperature): 250° C.

Reactive gas: nitrogen gas

### Process

One cycle including a series of processes (1) to (4) were repeated 700 times under the above-described conditions.
Process (1): (bis(dimethylsilyl)selenide) synthesized in Synthesis example 1 was used as a silicon precursor, and the silicon precursor was vaporized in a stainless steel bubbler container and deposited on a silicon substrate by injecting the silicon precursor onto the silicon substrate for about 0.5 seconds by using a nitrogen gas supplied at a flow rate of about 100 sccm as a carrier gas. Here, the silicon precursor was heated at a temperature of about 44° C.
Process (2): A purge process was performed by supplying the nitrogen gas at a flow rate of about 6000 sccm for about 4 seconds to remove unreacted sources and reaction by-products.
Process (3): A reactive gas was supplied at a flow rate of about 6000 sccm and RF power of about 150 W to about 400 W was applied to cause a reaction for about 9 seconds in a plasma atmosphere.
Process (4): A purge process was performed by supplying the nitrogen gas at a flow rate of about 6000 sccm for about 4 seconds to remove unreacted sources and reaction by-products.

A thickness of a thin film obtained by the process using an ellipsometer was measured, and components of the thin film obtained by the process was analyzed using an X-ray photoelectron spectroscopy.

Table 1 shows the thickness, growth rate, and refractive index of the silicon nitride film, which were measured via ellipsometer analysis.

TABLE 1

| RF power | Film thickness | Growth rate | |
|---|---|---|---|
| [W] | [Å] | [Å/cycle] | Refractive index |
| 150 | 151 | 0.22 | 1.83 |
| 200 | 163 | 0.23 | 1.84 |
| 400 | 190 | 0.27 | 1.91 |

Referring to Table 1, it can be seen that a refractive index of 1.83 to 1.91 was obtained and characteristics of the silicon nitride film were shown with an increase in plasma power. Therefore, it may be inferred that a silicon nitride film having few impurities may be formed by increasing plasma power or increasing plasma time.

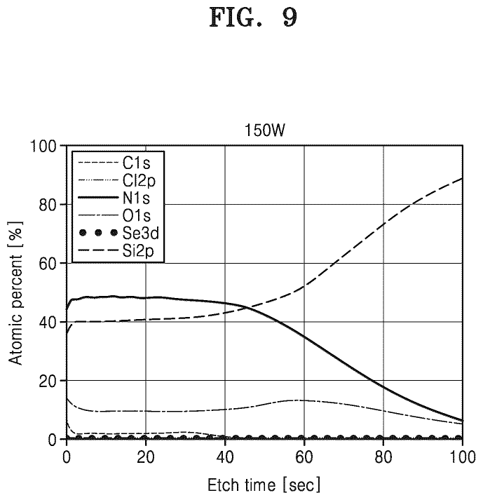

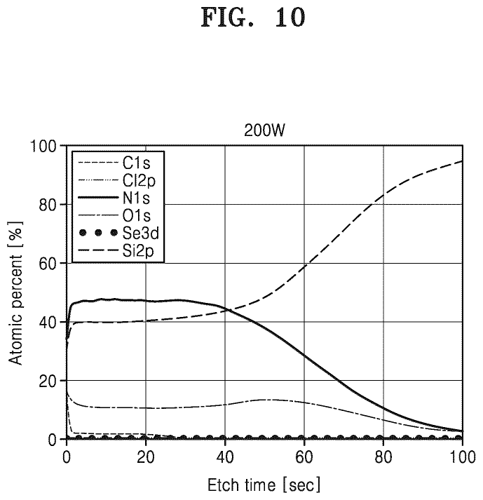

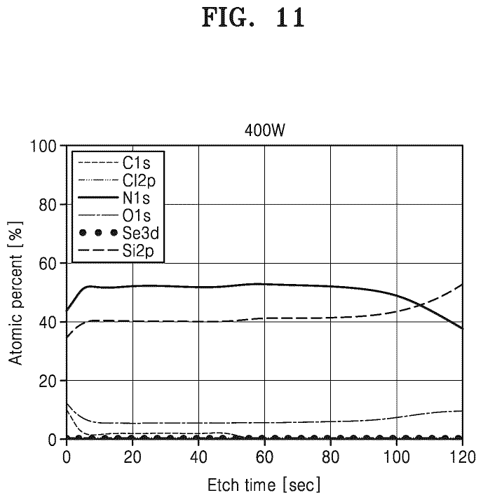

FIGS. 9 to 11 are each graphs showing the analysis results of components of thin films, which were formed in Silicon-containing film formation example 1 by using X-ray photoelectron spectroscopy. Here, FIG. 9 shows a case in which radio-frequency (RF) power was about 150 W, FIG. 10 shows a case in which RF power was about 200 W, and FIG. 11 shows a case in which RF power was about 400 W.

Table 2 shows the analysis results of the components of the thin film that was formed in Silicon-containing film formation example 1 by using X-ray photoelectron spectroscopy. That is, the contents of atoms included in the obtained thin films according to RF power are shown in Table 2.

TABLE 2

| RF power | Composition of film [at %] | | | | | Si/N |
|---|---|---|---|---|---|---|
| [W] | Si | N | O | C | Se | ratio |
| 150 | 40.3 | 48.3 | 9.6 | 1.8 | 0.0 | 0.83 |
| 200 | 40.2 | 47.8 | 10.7 | 1.3 | 0.0 | 0.84 |
| 400 | 40.9 | 52.5 | 5.6 | 1.0 | 0.0 | 0.78 |

From the results in Table 2, it was confirmed that the thin film obtained in Silicon-containing film formation example 1 did not include selenium atoms. Although the silicon compound of Formula 1 has a structure including a *—Si—Se—* bonding unit (* is a bonding position), selenol may be formed after Si—Se bonds are decomposed in the bonding unit. Because selenol is highly volatile, selenol may be relatively easily removed during a deposition process for forming a silicon-containing film.

In addition, referring to Table 2, it can be confirmed that the thin film obtained in Silicon-containing film formation example 1 was a silicon nitride film having a Si/N ratio of 0.78, which was similar to an ideal Si/N ratio. Oxygen atoms included in the thin film obtained in Silicon-containing film formation example 1 were generated due to the injection of gas (or outgassing) into a chamber during a deposition process. The contents of oxygen atoms shown in Table 2 are at an acceptable level.

### SILICON-CONTAINING FILM FORMATION EXAMPLE 2

### Formation of Silicon Nitride Film

A silicon nitride film was formed by a PEALD process using bis[(diisopropyl amino)methylsilyl]selenide, which was synthesized in Synthesis example 2, as a silicon precursor.

Conditions of the PEALD process for forming the silicon nitride film were as follows.

### Conditions

Reaction temperature (silicon substrate temperature): 250° C.

Reactive gas: nitrogen gas

### Process

One cycle including a series of processes (1) to (4) were repeated 340 times under the above-described conditions.
Process (1): bis[(diisopropyl amino)silyl]selenide synthesized in Synthesis example 2 was used as the silicon precursor, and the silicon precursor was vaporized in a stainless steel bubbler container and deposited on a silicon substrate by injecting the silicon precursor onto the silicon substrate for about 0.5 seconds by using a nitrogen gas, which was supplied at a flow rate of about 25 sccm as a carrier gas. Here, the silicon precursor was heated at a temperature of about 95° C.
Process (2): A purge process was performed by supplying the nitrogen gas at a flow rate of about 6000 sccm for about 4 seconds to remove unreacted sources and reaction by-products.
Process (3): A reactive gas was supplied at a flow rate of about 6000 sccm and RF power of about 150 W was applied to cause a reaction for about 9 seconds in a plasma atmosphere.
Process (4): A purge process was performed by supplying the nitrogen gas at a flow rate of about 6000 sccm for about 4 seconds to remove unreacted sources and reaction by-products.

A thickness of a thin film obtained by the process using an ellipsometer was measured, and components of the thin film obtained by the process was analyzed using an X-ray photoelectron spectroscopy.

Table 3 shows the thickness, growth rate, and refractive index of the thin film, which were measured via ellipsometer analysis.

TABLE 3

| RF power | Film thickness | Growth rate | |
|---|---|---|---|
| [W] | [Å] | [Å/cycle] | Refractive index |
| 150 | 243 | 0.35 | 1.89 |

From the results of Table 3, it was confirmed that a deposition rate of the silicon nitride film was relatively high, and a refractive index of the silicon nitride film was relatively high. From the above results, it can be seen that a silicon nitride film having few impurities may be formed by controlling plasma power and a plasma time.

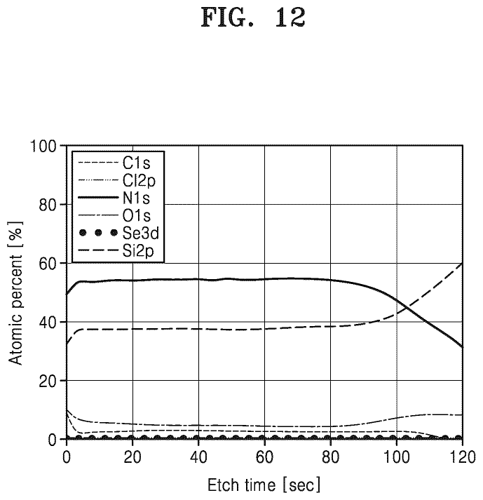

FIG. 12 is a graph showing the analysis results of components of a thin film that was formed in Silicon-containing film formation example 2 by using X-ray photoelectron spectroscopy.

Table 4 shows the analysis results of components of a thin film that was formed in Silicon-containing film formation example 2 by using X-ray photoelectron spectroscopy.

TABLE 4

| RF power | Composition of film [at %] | | | | | Si/N |
|---|---|---|---|---|---|---|
| [W] | Si | N | O | C | Se | ratio |
| 150 | 37.6 | 54.5 | 4.9 | 2.9 | 0.0 | 0.69 |

From the results of Table 4, it was confirmed that the thin film obtained in Silicon-containing film formation example 2 did not include selenium atoms. Although the silicon compound of Formula 10 has a structure including a *—Si—Se—* bonding unit (* is a bonding position), selenol may be formed after Si-Se bonds are decomposed in the bonding unit. Because selenol is highly volatile, selenol may be relatively easily removed during a deposition process for forming a silicon-containing film. In addition, from the results of Table 4, it was confirmed that the thin film obtained in Silicon-containing film formation example 2 was a silicon nitride film with a silicon/nitrogen ratio of about 0.69.

### Estimation of Etching Characteristics

To estimate a wet etching process on the thin film obtained in Silicon-containing film formation example 1, diluted hydrofluoric acid (H₂O:HF=200:1) was used as an etchant.

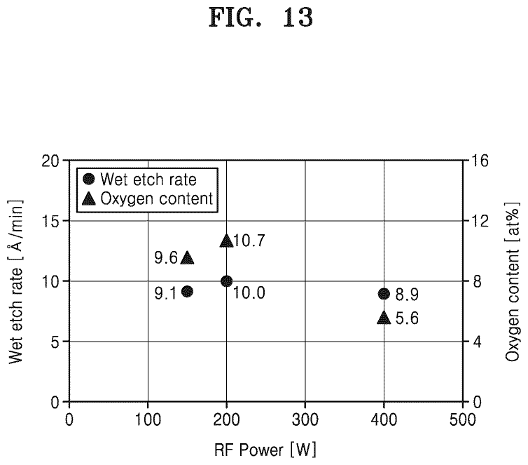

FIG. 13 is a graph showing the estimation results of a wet etching process on the thin film obtained in Silicon-containing film formation example 1.

In FIG. 13, a result indicated by “9.6” shows a case in which the content of oxygen atoms in a silicon nitride film was about 9.6 at %, a result indicated by “10.7” shows a case in which the content of oxygen atoms in the silicon nitride film was about 10.7 at %, and a result indicated by “5.6” shows a case in which the content of oxygen atoms in the silicon nitride film was about 5.6 at %.

From the results of FIG. 13, it can be seen that the thin film obtained in Silicon-containing film formation example 1 had an etch rate of about 8.9 Å/min to about 10.0 Å/min and exhibited excellent etching characteristics. In addition, it was confirmed that the etch rate was reduced with a reduction in the content of oxygen atoms in the silicon-containing film.

While the inventive concept has been particularly shown and described with reference to some example embodiments thereof, it will be understood that various changes in form and details may be made therein without departing from the scope of the following claims.

1.-20. (canceled)

21. A silicon compound of General formula (1): 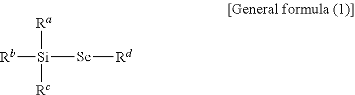
wherein each of R^{a}, R^{b}, and R^{c} is independently a hydrogen atom, a halogen atom, a C1-C7 straight-chain alkyl group, a C3-C7 branched alkyl group, an amino group, a C1-C7 alkyl amino group, or a C1-C7 alkoxy group,
R^{d} is a C1-C7 straight-chain alkyl group, a C3-C7 branched alkyl group, a C1-C7 alkyl amino group, or a substituted or unsubstituted silyl group of *—Si(X¹)(X²)(X³), wherein each of X¹, X², and X³ is independently a hydrogen atom, a halogen atom, a C1-C7 straight-chain alkyl group, a C3-C7 branched alkyl group, an amino group, a C1-C7 alkyl amino group, or a C1-C7 alkoxy group, and * is a bonding site, and
wherein at least one of R^{a}, R^{b}, R^{c}, and R^{d} comprises a nitrogen atom.

22. The silicon compound of claim 21, wherein at least one of R^{a}, R^{b}, and R^{c} is the amino group or the C1-C7 alkyl amino group.

23. The silicon compound of claim 21, wherein at least one of R^{a}, R^{b}, and R^{c} is the C1-C7 alkyl amino group.

24. The silicon compound of claim 21, wherein, when R^{b} is the C1-C7 alkyl amino group and R^{d} is the C1-C7 straight-chain alkyl group or the C3-C7 branched alkyl group, R^{b} is connected to R^{d} to form a ring.

25. The silicon compound of claim 21, wherein one of R^{a}, R^{b}, and R^{c} is the C1-C7 alkyl amino group, and the others of R^{a}, R^{b}, and R^{c} are each the hydrogen atom, the halogen atom, the C1-C7 straight-chain alkyl group, or the C3-C7 branched alkyl group.

26. The silicon compound of claim 21, wherein, in General formula (1), R^{d} is a substituted or unsubstituted silyl group of *—Si(X¹)(X²)(X³), wherein each of X¹, X², and X³ is the same as defined in General formula (1), and at least one of X¹, X², and X³ is the amino group or the C1-C7 alkyl amino group.

27. The silicon compound of claim 26, wherein one of R^{a}, R^{b}, and R^{c} is the C1-C7 alkyl amino group, and the others of R^{a}, R^{b}, and R^{c} are each the hydrogen atom, the halogen atom, the C1-C7 straight-chain alkyl group, or the C3-C7 branched alkyl group, and
wherein one of X¹, X², and X³ is the C1-C7 alkyl amino group, and the others of X¹, X², and X³ are each the hydrogen atom, the halogen atom, the C1-C7 straight-chain alkyl group, or the C3-C7 branched alkyl group.

28. The silicon compound of claim 21, wherein the silicon compound comprises a structure of General formula (2): 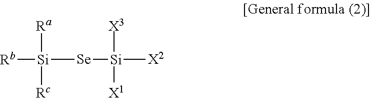
wherein R^{a}, R^{b}, R^{c}, X¹, X², and X³ are the same as defined in General formula (1), and
at least one of X¹, X², and X³ is an amino group or a C1-C7 alkyl amino group.

29. The silicon compound of claim 21, wherein the silicon compound is one of General formulae (3), (4), and (5): 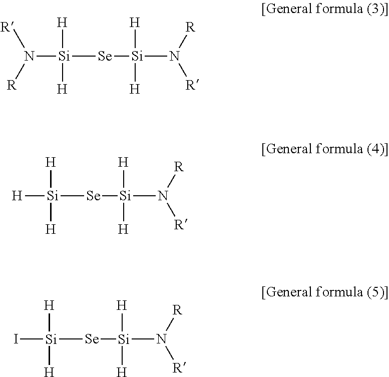
wherein each of R and R′ is independently a hydrogen atom, a C1-C4 straight-chain alkyl group, or a C3-C4 branched alkyl group.

30. The silicon compound of claim 21, wherein R^{b} is the C1-C7 alkyl amino group, R^{d} is the C1-C7 straight-chain alkyl group or the C3-C7 branched alkyl group, and R^{b} is connected to R^{d} to form a cyclic structure comprising a bonding unit of *—Se—Si(R¹)(R²)—N(R³)—*, wherein each of R¹ and R² is independently a hydrogen atom, a halogen atom, a C1-C7 straight-chain alkyl group, a C3-C7 branched alkyl group, an amino group, a C1-C7 alkyl amino group, or a C1-C7 alkoxy group, R³ is a hydrogen atom, a C1-C7 straight-chain alkyl group, or a C3-C7 branched alkyl group, and * is a bonding site.

31. The silicon compound of claim 21, wherein R^{b} is the C1-C7 alkyl amino group, R^{d} is the C1-C7 straight-chain alkyl group or the C3-C7 branched alkyl group, and R^{b} is connected to R^{d} to form a cyclic structure represented by General formula (8): 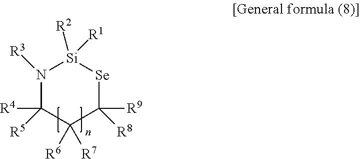
wherein each of R¹ and R² is independently a hydrogen atom, a halogen atom, a C1-C7 straight-chain alkyl group, a C3-C7 branched alkyl group, an amino group, a C1-C7 alkyl amino group, or a C1-C7 alkoxy group,
each of R³, R⁴, R⁵, R⁶, R⁷, R⁸, and R⁹ is independently a hydrogen atom, a C1-C7 straight-chain alkyl group, or a C3-C7 branched alkyl group, and
n is 0 or 1.

32. The silicon compound of claim 21, wherein the silicon compound of General formula (1) is liquid at a temperature of 25° C.

33. The silicon compound of claim 21, wherein, in General formula (1), at least one of R^{a}, R^{b}, R^{c}, and R^{d} comprises an iodine atom.

34. The silicon compound of claim 21, wherein the silicon compound of General formula (1) has a structure of General formula (2): 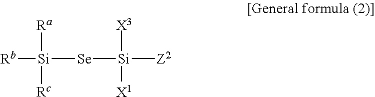
wherein each of R^{a}, R^{b}, R^{c}, X¹, X², and X³ is independently a hydrogen atom, an iodine atom, a C1-C4 straight-chain alkyl group, a C3-C4 branched alkyl group, an amino group, a C1-C4 alkyl amino group, or a C1-C4 alkoxy group, and
wherein at least one of R^{a}, R^{b}, R^{c}, X¹, X², and X³ is an amino group or a C1-C4 alkyl amino group.

35. A silicon compound as a silicon precursor for forming a silicon-containing film, the silicon compound represented by General formula (1): 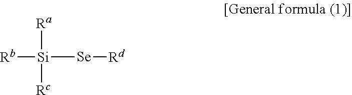
wherein each of R^{a}, R^{b}, and R^{c} is independently a hydrogen atom, a halogen atom, a C1-C7 straight-chain alkyl group, a C3-C7 branched alkyl group, an amino group, a C1-C7 alkyl amino group, or a C1-C7 alkoxy group,
R^{d} is a C1-C7 straight-chain alkyl group, a C3-C7 branched alkyl group, a C1-C7 alkyl amino group, or a substituted or unsubstituted silyl group of *—Si(X¹)(X²)(X³), wherein each of X¹, X², and X³ is independently a hydrogen atom, a halogen atom, a C1-C7 straight-chain alkyl group, a C3-C7 branched alkyl group, an amino group, a C1-C7 alkyl amino group, or a C1-C7 alkoxy group, and * is a bonding site, and
wherein at least one of R^{a}, R^{b}, R^{c}, and R^{d} is the amino group or the C1-C7 alkyl amino group.

36. The silicon compound of claim 35, wherein the silicon compound comprises a structure of General formula (2): 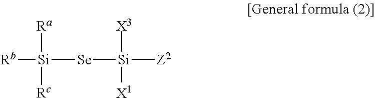
wherein R^{a}, R^{b}, R^{c}, X¹, X², and X³ are the same as defined in General formula (1), and
at least one of X¹, X², and X³ is an amino group or a C1-C7 alkyl amino group.

37. The silicon compound of claim 35, wherein R^{b} is the C1-C7 alkyl amino group, R^{d} is the C1-C7 straight-chain alkyl group or the C3-C7 branched alkyl group, and R^{b} is connected to R^{d} to form a cyclic structure represented by General formula (8): 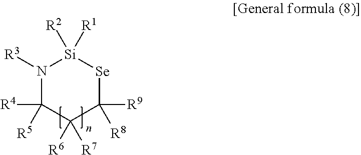
wherein each of R¹ and R² is independently a hydrogen atom, a halogen atom, a C1-C7 straight-chain alkyl group, a C3-C7 branched alkyl group, an amino group, a C1-C7 alkyl amino group, or a C1-C7 alkoxy group,
each of R³, R⁴, R⁵, R⁶, R⁷, R⁸, and R⁹ is independently a hydrogen atom, a C1-C7 straight-chain alkyl group, or a C3-C7 branched alkyl group, and
n is 0 or 1.

38. A method of manufacturing an integrated circuit device, the method comprising forming a silicon-containing film on a substrate using a silicon compound as a silicon precursor, the silicon compound represented by General formula (1): 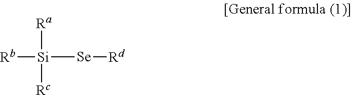
wherein each of R^{a}, R^{b}, and R^{c} is independently a hydrogen atom, a halogen atom, a C1-C7 straight-chain alkyl group, a C3-C7 branched alkyl group, an amino group, a C1-C7 alkyl amino group, or a C1-C7 alkoxy group,
R^{d} is a C1-C7 straight-chain alkyl group, a C3-C7 branched alkyl group, a C1-C7 alkyl amino group, or a substituted or unsubstituted silyl group of *—Si(X¹)(X²)(X³), wherein each of X¹, X², and X³ is independently a hydrogen atom, a halogen atom, a C1-C7 straight-chain alkyl group, a C3-C7 branched alkyl group, an amino group, a C1-C7 alkyl amino group, or a C1-C7 alkoxy group, and * is a bonding site, and
wherein at least one of R^{a}, R^{b}, R^{c}, and R^{d} comprises a nitrogen atom.

39. The method of claim 38, wherein at least one of R^{a}, R^{b}, R^{c}, and R^{d} is the amino group or the C1-C7 alkyl amino group,
wherein when R^{a}is a substituted or unsubstituted silyl group of *—Si(X¹)(X²)(X³), the silicon compound comprises a structure of General formula (2): 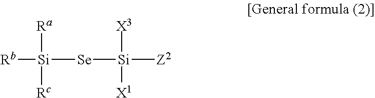
wherein R^{a}, R^{b}, R^{c}, X¹, X², and X³ are the same as defined in General formula (1), and at least one of X¹, X², and X³ is an amino group or a C1-C7 alkyl amino group, and
wherein when R^{b} is the C1-C7 alkyl amino group and R^{d} is the C1-C7 straight-chain alkyl group or the C3-C7 branched alkyl group, R^{b} is connected to R^{d} to form a cyclic structure represented by General formula (8): 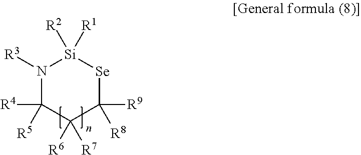
wherein each of R¹ and R² is independently a hydrogen atom, a halogen atom, a C1-C7 straight-chain alkyl group, a C3-C7 branched alkyl group, an amino group, a C1-C7 alkyl amino group, or a C1-C7 alkoxy group,
each of R³, R⁴, R⁵, R⁶, R⁷, R⁸, and R⁹ is independently a hydrogen atom, a C1-C7 straight-chain alkyl group, or a C3-C7 branched alkyl group, and
n is 0 or 1.

40. The method of claim 38, wherein the silicon compound is one of General formulae (3), (4), (5), (9), and (10), and Formulae 13-20: 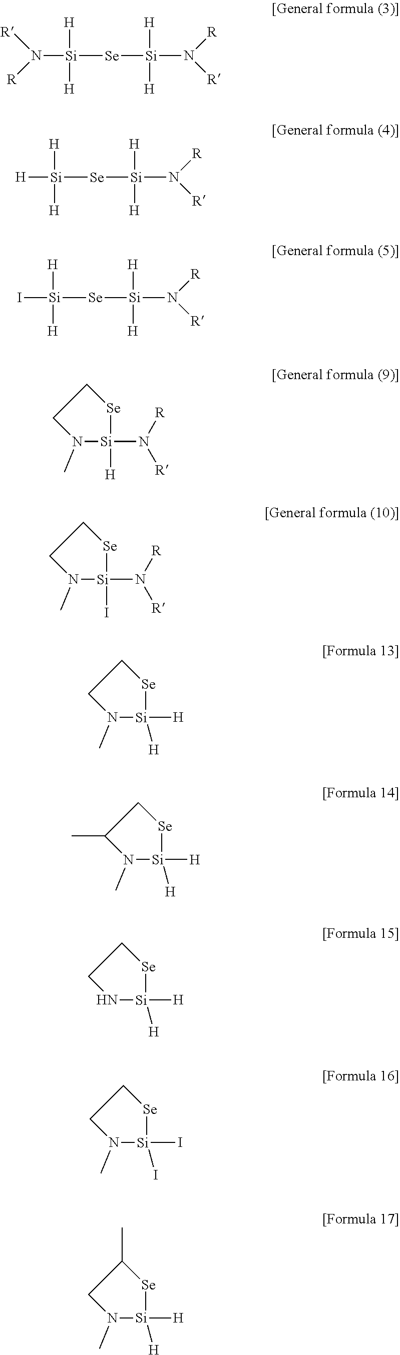 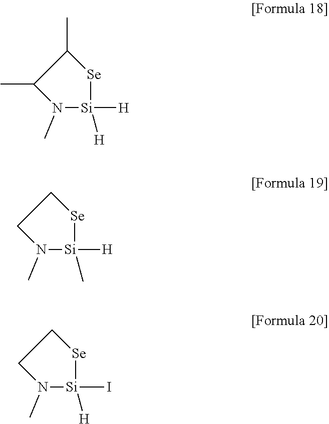
wherein, in General formulae (3), (4), (5), (9), and (10), each of R and R′ is independently a hydrogen atom, a C1-C4 straight-chain alkyl group, or a C3-C4 branched alkyl group.
